(19) United States
(12) Patent Application Publication
(10) Pub. No.: US 2026/0206532 A1
(43) Pub. Date: Jul. 16, 2026

(54) TRANSPORT SYSTEM AND METHOD FOR TRANSPORTING WORKPIECE

(71) Applicant: KABUSHIKI KAISHA YASKAWA DENKI, Kitakyushu-shi (JP)

(72) Inventors: Mina ORII, Kitakyushu-shi (JP); Akira TAJIMA, Kitakyushu-shi (JP); Akihito TOYOTA, Kitakyushu-shi (JP); Miyabi TERASHIMA, Kitakyushu-shi (JP); Hiromitsu AKAE, Kitakyushu-shi (JP)

(73) Assignee: KABUSHIKI KAISHA YASKAWA DENKI, Kitakyushu-shi (JP)

(21) Appl. No.: 19/449,373

(22) Filed: Jan. 14, 2026

(30) Foreign Application Priority Data
Jan. 15, 2025 (JP) 2025-005839

(51) Int. Cl. H10P 72/30; B65G 47/244; B65G 54/02

(52) U.S. Cl. CPC H10P 72/3204; B65G 47/244; B65G 54/02; H10P 72/3202

(57) ABSTRACT

A substrate transport system includes a first chamber including a transport path along which a workpiece is configured to be transported, a second chamber arranged around the first chamber and including an opening/closing door, stators arranged along the transport path in the first chamber, a movable element including a magnet and being configured to float on and move along the transport path to carry the workpiece supported on a support into and out of the second chamber, and a controller configured to control the movable element to change an orientation of the movable element so as to change an orientation of the support at a position where at least a part of one of the stators provided in front of the opening/closing door and at least a part of the movable element overlap with each other when viewed in a vertical direction.

### CROSS-REFERENCE TO RELATED APPLICATIONS

The present application claims priority under 35 U.S.C. §119 to Japanese Patent Application No. 2025-005839, filed January 15, 2025. The contents of this application are incorporated herein by reference in their entirety.

### BACKGROUND

### TECHNICAL FIELD

The present disclosure relates to a transport system and a method for transporting a workpiece.

### Discussion of the Background

Japanese Unexamined Patent Application Publication No. 2018-504784 describes a semiconductor processing facility used for transferring a semiconductor substrate between processing chambers.

The semiconductor processing equipment includes a planar motor having an array of coils, and a substrate carrier having magnets and levitated and positionally controlled by interaction of magnetic fields generated by the coils and magnetic fields generated by the magnets. The substrate carrier has a substrate supporting surface on which a substrate is placed and transports the substrate between the processing chambers.

### SUMMARY

According to one aspect of the present disclosure, a transport system includes a first chamber including a transport path along which a workpiece is configured to be transported; a second chamber arranged around the first chamber and including an opening/closing door; a plurality of stators arranged along the transport path in the first chamber, each of the plurality of stators including a coil; a movable element including a magnet and a support configured to support the workpiece, the moving element being configured to float on and move along the transport path to carry the workpiece supported on the support into and out of the second chamber; and a controller configured to control the movable element to change an orientation of the movable element so as to change an orientation of the support at a position where at least a part of one of the plurality of stators provided in front of the opening/closing door and at least a part of the movable element overlap with each other when viewed in a vertical direction.

According to another aspect of the present disclosure, the transport system includes a first chamber including a transport path along which a workpiece is configured to be transported; a second chamber arranged around the first chamber and including an opening/closing door; a plurality of stators arranged along the transport path in the first chamber, each of the plurality of stators including a coil; a movable element including a magnet and a support configured to support the workpiece, the moving element being configured to float on and move along the transport path to carry the workpiece supported on the support into and out of the second chamber; and a controller configured to control the movable element to change an orientation of the movable element so as to change an orientation of the support at a position where at least a part of one of the plurality of stators provided in front of the opening/closing door and at least a part of the movable element overlap with each other when viewed in a vertical direction, and configured to adjust at least one of a position and an orientation of the movable element at a position where at least a part of one stator arranged immediately before the opening/closing door among the plurality of stators and at least a part of the movable element overlap when viewed in the vertical direction such that the workpiece is positioned at a predetermined position in the second chamber.

According to further aspect of the present disclosure, a method for transporting a workpiece includes providing a first chamber including a transport path along which a workpiece is configured to be transported; providing a second chamber arranged around the first chamber and including an opening/closing door; providing a plurality of stators arranged along the transport path in the first chamber, each of the plurality of stators including a coil; providing a movable element including a magnet and a support configured to support the workpiece, the moving element being configured to float on and move along the transport path to carry the workpiece supported on the support into and out of the second chamber; and changing an orientation of the movable element so as to change an orientation of the support at a position where at least a part of one of the plurality of stators provided in front of the opening/closing door and at least a part of the movable element overlap with each other when viewed in a vertical direction.

### BRIEF DESCRIPTION OF THE DRAWINGS

A more complete appreciation of the present disclosure and many of the attendant advantages thereof will be readily obtained as the same becomes better understood by reference to the following detailed description when considered in connection with the accompanying drawings.

FIG. 1 is a diagram schematically illustrating an example of an overall configuration of a substrate transport system.

FIG. 2 is a diagram schematically showing an example of a coil configuration of a stator.

FIG. 3 is a diagram schematically showing an example of a magnet configuration of the movable element.

FIG. 4 is a perspective view showing an example of the degree of freedom of the operation of the movable element in the planar motor constituted by the stator and the movable element.

FIG. 5A is a diagram schematically illustrating a case of the movable element being rotated about the rotation axis at a position where the rotation axis of the movable element overlaps with an approximately center of one of the stators provided in front of the opening/closing door.

FIG. 5B is a diagram schematically illustrating a case where the movable element is rotated about the rotation axis of the movable element at a position shifted from the center of one of the stators provided in front of the opening/closing door.

FIG. 6 is a diagram schematically illustrating an extension/contraction operation of a substrate support which is a single-arm extension/contraction type arm.

FIG. 7A is a diagram showing an example of the operation of the movable element having the single-arm telescopic substrate support when the movable element transfers a processed semiconductor substrate from the processing chamber to the load lock chamber.

FIG. 7B is a diagram showing an example of the operation of the movable element having the single-arm telescopic substrate support when the movable element transfers a processed semiconductor substrate from the processing chamber to the load lock chamber.

FIG. 7C is a diagram showing an example of the operation of the movable element having the single-arm telescopic substrate support when the movable element transfers a processed semiconductor substrate from the processing chamber to the load lock chamber.

FIG. 7D is a diagram showing an example of the operation of the movable element having the single-arm telescopic substrate support when the movable element transfers a processed semiconductor substrate from the processing chamber to the load lock chamber.

FIG. 7E is a diagram showing an example of the operation of the movable element having the single-arm telescopic substrate support when the movable element transfers a processed semiconductor substrate from the processing chamber to the load lock chamber.

FIG. 7F is a diagram showing an example of the operation of the movable element having the single-arm telescopic substrate support when the movable element transfers a processed semiconductor substrate from the processing chamber to the load lock chamber.

FIG. 8A is a diagram showing a part of an operation example in the case where the movable element including the single-arm telescopic substrate support passes through the second transport path and transports the processed semiconductor substrate from the processing chamber to the load lock chamber.

FIG. 8B is a diagram showing a part of an operation example in the case where the movable element including the single-arm telescopic substrate support passes through the second transport path and transports the processed semiconductor substrate from the processing chamber to the load lock chamber.

FIG. 8C is a diagram showing a part of an operation example in the case where the movable element including the single-arm telescopic substrate support passes through the second transport path and transports the processed semiconductor substrate from the processing chamber to the load lock chamber.

FIG. 9 is a diagram schematically illustrating an extension/contraction operation of a substrate support which is a double-arm extension/contraction type arm.

FIG. 10A is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10B is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10C is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10D is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10E is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10F is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10G is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10H is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10I is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10J is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10K is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 10L is a diagram showing an example of operation in the case where the movable element having the double-arm telescopic substrate support transports an unprocessed semiconductor substrate from the load lock chamber to the processing chamber and transports a processed semiconductor substrate from the processing chamber to the load lock chamber.

FIG. 11 is a diagram schematically illustrating a configuration of a substrate support which is a single-arm non-extendable arm.

FIG. 12A is a diagram showing an example of operation in the case where the movable element having the single-arm non-extendable substrate support transports a processed semiconductor substrate from the processing chamber to the load lock chamber.

FIG. 12B is a diagram showing an example of operation in the case where the movable element having the single-arm non-extendable substrate support transports a processed semiconductor substrate from the processing chamber to the load lock chamber.

FIG. 12C is a diagram showing an example of operation in the case where the movable element having the single-arm non-extendable substrate support transports a processed semiconductor substrate from the processing chamber to the load lock chamber.

FIG. 12D is a diagram showing an example of operation in the case where the movable element having the single-arm non-extendable substrate support transports a processed semiconductor substrate from the processing chamber to the load lock chamber.

FIG. 12E is a diagram showing an example of operation in the case where the movable element having the single-arm non-extendable substrate support transports a processed semiconductor substrate from the processing chamber to the load lock chamber.

FIG. 12F is a diagram showing an example of operation in the case where the movable element having the single-arm non-extendable substrate support transports a processed semiconductor substrate from the processing chamber to the load lock chamber.

FIG. 13 is a diagram schematically illustrating a configuration of a substrate support which is a double-arm non-extendable arm.

FIG. 14A is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14B is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14C is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14D is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14E is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14F is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14G is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14H is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14I is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14J is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14K is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14L is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 14M is a diagram showing an example of operation in the case where the movable element having the double-arm non-extendable substrate support conveys an unprocessed semiconductor substrate from the load lock chamber to the processing chamber and conveys a processed semiconductor substrate from the processing chamber to the load lock chamber.

FIG. 15A is a diagram schematically illustrating an example of the position adjustment operation of the movable element.

FIG. 15B is a diagram schematically illustrating an example of the position adjustment operation of the movable element.

FIG. 16A is a diagram showing an operation example in the case where the movable element provided with, for example, a single-arm telescopic type substrate support conveys an unprocessed semiconductor substrate from the load lock chamber to the processing chamber in a modification in which the movable element is rotated in front of the load lock chamber.

FIG. 16B is a diagram showing an operation example in the case where the movable element provided with, for example, a single-arm telescopic type substrate support conveys an unprocessed semiconductor substrate from the load lock chamber to the processing chamber in a modification in which the movable element is rotated in front of the load lock chamber.

FIG. 16C is a diagram showing an operation example in the case where the movable element provided with, for example, a single-arm telescopic type substrate support conveys an unprocessed semiconductor substrate from the load lock chamber to the processing chamber in a modification in which the movable element is rotated in front of the load lock chamber.

FIG. 16D is a diagram showing an operation example in the case where the movable element provided with, for example, a single-arm telescopic type substrate support conveys an unprocessed semiconductor substrate from the load lock chamber to the processing chamber in a modification in which the movable element is rotated in front of the load lock chamber.

FIG. 16E is a diagram showing an operation example in the case where the movable element provided with, for example, a single-arm telescopic type substrate support conveys an unprocessed semiconductor substrate from the load lock chamber to the processing chamber in a modification in which the movable element is rotated in front of the load lock chamber.

FIG. 16F is a diagram showing an operation example in the case where the movable element provided with, for example, a single-arm telescopic type substrate support conveys an unprocessed semiconductor substrate from the load lock chamber to the processing chamber in a modification in which the movable element is rotated in front of the load lock chamber.

FIG. 17 is a diagram schematically illustrating an example of an overall configuration of the substrate transport system in a modification in which a temporary storage place is arranged.

FIG. 18A is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18B is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18C is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18D is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18E is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18F is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18G is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18H is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18I is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18J is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18K is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18L is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18M is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18N is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18O is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18P is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18Q is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

FIG. 18R is a diagram showing an operation example in the case where the movable element including, for example, the single-arm extension/contraction type substrate support conveys an unprocessed semiconductor substrate from the load lock chamber to the processing chamber and conveys a processed semiconductor substrate from the processing chamber to the load lock chamber in the modification example in which the temporary storage place is provided.

### DESCRIPTION OF THE EMBODIMENTS

Hereinafter, embodiments will be described with reference to the drawings.

### Overall configuration of substrate transport system

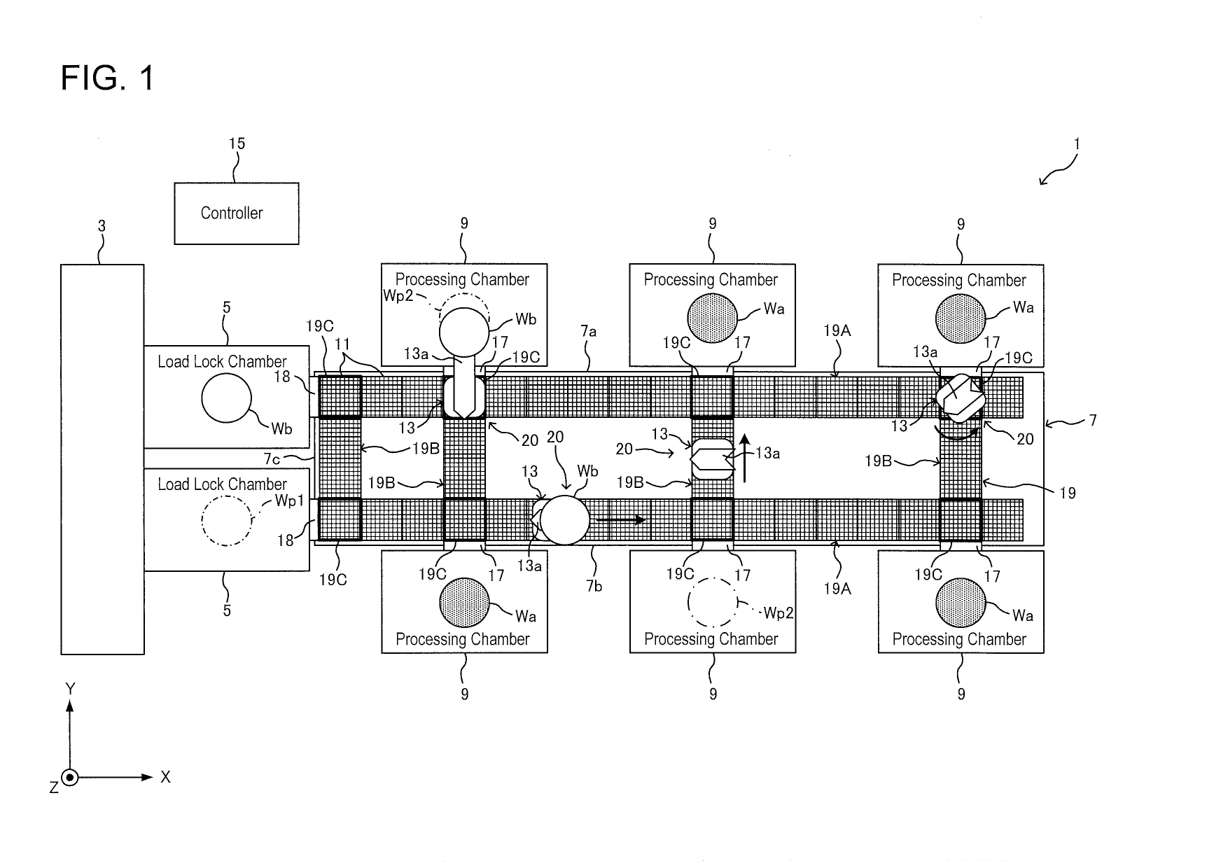

An example of an overall configuration of a substrate transport system according to an embodiment will be described with reference to FIG. 1. The substrate transport system 1 (an example of the transport system 1) is a system that transfers a semiconductor substrate W (an example of a workpiece) in a vacuum environment and performs a predetermined process on the semiconductor substrate W. The semiconductor substrate W is also referred to as a semiconductor wafer. In the present embodiment, a processed semiconductor substrate is denoted by Wa, an unprocessed semiconductor substrate is denoted by Wb, and a semiconductor substrate is denoted by W when it is not distinguished whether the semiconductor substrate is processed or unprocessed. In each drawing, the processed semiconductor substrate Wa is indicated by dot hatching, and the unprocessed semiconductor substrate Wb is indicated by white.

FIG. 1 is a diagram schematically illustrating an example of an overall configuration of a substrate transport system. As illustrated in FIG. 1, the substrate transport system 1 includes an atmospheric transfer chamber 3, a load lock chamber 5, a vacuum transfer chamber 7, a plurality of processing chambers 9, a stator 11, a movable element 13, and a controller 15.

The atmospheric transfer chamber 3 is in an atmospheric atmosphere, and an atmospheric transfer device (not illustrated) for transferring the semiconductor substrate W is provided therein. The atmospheric transfer device takes out an unprocessed semiconductor substrate Wb accommodated in a load port (not illustrated) and places the unprocessed semiconductor substrate Wb on the placing table oWp1 of the load lock chamber 5. The atmospheric transfer device takes out the processed semiconductor substrate Wa placed on the mounting table Wp1 of the load lock chamber 5 and accommodates the processed semiconductor substrate Wa in the load port.

The load lock chambers 5 (an example of a second chamber) are provided around the vacuum transfer chamber 7. In the example shown in FIG. 1, for example, two load lock chambers 5 are connected to the wall portion 7c of the vacuum transfer chamber 7 via the opening/closing door 18. The load lock chamber 5 has a mounting table Wp1 on which the semiconductor substrate W is mounted. In each drawing, the mounting table Wp1 of the load lock chamber 5 is indicated by a one dot chain line. The load lock chamber 5 controls the pressure between the atmospheric pressure and the vacuum when the semiconductor substrate W is transferred between the atmospheric transfer chamber 3 and the vacuum transfer chamber 7. The load lock chamber 5 includes an opening/closing door 18 that opens and closes an opening of the load lock chamber 5. The opening/closing door 18 is also referred to as a gate valve. In each of the load lock chambers 5, the loading of the semiconductor substrate Wa and the unloading of the semiconductor substrate Wb are performed by the substrate support 13a of the movable element 13 in a state where the opening/closing door 18 is opened.

The inside of the vacuum transfer chamber 7 (an example of a first chamber) is depressurized to a vacuum atmosphere, and the semiconductor substrate W is transferred in the vacuum atmosphere. In the example shown in FIG. 1, the vacuum transfer chamber 7 is formed to have, for example, a substantially rectangular shape when viewed from above. A plurality of processing chambers 9 (for example, three on each side, for a total of six) are connected, via respective opening/closing door 17, to the opposing long-side wall portions 7a and 7b of the vacuum transfer chamber 7. A plurality of (e.g., two) load lock chambers 5 are connected to the other wall portion on the short side of the vacuum transfer chamber 7 via opening/closing doors 18. In the present embodiment, the longitudinal direction of the vacuum transfer chamber 7, that is, the direction in which the plurality of processing chambers 9 having the opening/closing doors 17 facing the same direction are arranged side by side along the wall portion 7a or the wall portion 7b of the vacuum transfer chamber 7 is defined as an X-axis direction (an example of a first direction). In addition, a short direction of the vacuum transfer chamber 7, that is, a direction in which the two processing chambers 9 having the opening/closing doors 17 facing opposite directions face each other is defined as a Y-axis direction (an example of a second direction). The vertical direction (up-down direction) is defined as a Z-axis direction. The X-axis direction, the Y-axis direction, and the Z-axis direction are orthogonal to each other. Note that the X-axis direction and the Y-axis direction are not necessarily orthogonal to each other, and may be intersecting directions. In this case, the vacuum transfer chamber 7 may have a shape other than a rectangle (for example, a parallelogram, a trapezoid, or the like).

The vacuum transfer chamber 7 includes a transport path 19 through which the semiconductor substrate W is transferred. The transport path 19 is formed by arranging a plurality of stators 11 in a line. The transport path 19 includes a first transport path 19A and a second transport path 19B, and is formed in a substantially ladder shape (ladder shape). The first transport path 19A is formed by arranging a plurality of stators 11 in a line along the X-axis direction. In the vacuum transfer chamber 7, two first transport paths 19A extending substantially parallel to the X-axis direction are provided. The two first transport paths 19A are separated from each other with a gap corresponding to the size of at least one of the stators 11 in the Y-axis direction. In the present embodiment, the two first transport paths 19A are separated from each other with a gap corresponding to the dimensions of the two stators 11, but may be separated from each other with a gap corresponding to the dimensions of one or three or more stators 11. The number of the first transport paths 19A is not limited to two, and may be one or three or more.

The second transport path 19B is formed by arranging at least one of the stators 11 in a line along the Y-axis direction, and connects the two first transport paths 19A in the Y-axis direction. In the example shown in FIG. 1, for example, four second transport paths 19B are provided. Among the four second transport paths 19B, three second transport paths 19B other than the second transport path 19B immediately before the load lock chamber 5 connect the two first transport paths 19A at a position in front of the opening/closing door 17 of the processing chamber 9 in the Y-axis direction. Each second transport path 19B is formed by, for example, two stators 11. The second transport path 19B may be formed by one stator 11 or may be formed by three or more stators 11.

The transport path 19 has a connecting portion 19C where the first transport path 19A and the second transport path 19B intersect each other. The connecting portion 19C coincides with the position of the stator 11 provided immediately before the opening/closing doors 17, 18. In FIG. 1, the connecting portion 19C is indicated by a thick line.

The stators 11 each include a plurality of coils and are provided along the transport path 19 in the vacuum transfer chamber 7. The stator 11 is formed in a substantially quadrangular shape (a rectangular shape or a square shape) when viewed from the Z-axis direction. Each of the movable elements 13 includes a plurality of magnets, and moves while floating on the transport path 19 to transport the semiconductor substrate W. The stator 11 and the movable element 13 constitute a planar motor 20. The movable element 13 is levitated by the interaction between the magnetic field generated by the coil of the stator 11 and the magnetic field generated by the magnet of the movable element 13, and the position of the movable element 13 is controlled by the controller 15. The movable element 13 includes a substrate support 13a (an example of a support) that supports the semiconductor substrate W. The movable element 13 transfers the semiconductor substrate W supported by the substrate support 13a between the load lock chamber 5 and the processing chamber 9 or between the plurality of processing chambers 9, and carries the semiconductor substrate W into and out of the load lock chamber 5 and the processing chamber 9. Although four movable elements 13 are shown in FIG. 1, for example, the number of movable elements 13 may be one or more than one other than four.

The processing chamber 9 (an example of a second chamber) is provided around the vacuum transfer chamber 7. In the example shown in FIG. 1, for example, six processing chambers 9 are connected to the wall portions 7a and 7b, respectively, three by three via the opening/closing door 17. The three processing chambers 9 connected to the wall portion 7a are arranged along the X-axis direction, and the three processing chambers 9 connected to the wall portion 7b are arranged along the X-axis direction. The processing chamber 9 has a mounting table Wp2 on which the semiconductor substrate W is mounted. In each drawing, the mounting table Wp2 of the processing chamber 9 is indicated by a one dot chain line. In each processing chamber 9, a predetermined process is performed on the unprocessed semiconductor substrate Wb placed on the stage Wp2. The predetermined processing includes, for example, a film forming processing, an etching processing, an ashing processing, a cleaning processing, and the like. The number of the processing chambers 9 is not particularly limited, and may be one or more than six depending on the number of processes to be performed. The processing chamber 9 includes an opening/closing door 17 that opens and closes an opening of the processing chamber 9. The opening/closing door 17 is also referred to as a gate valve. In each processing chamber 9, the semiconductor substrate Wb is carried in and the semiconductor substrate Wa is carried out by the substrate support 13a of the movable element 13 in a state where the opening/closing door 17 is opened.

The controller 15 controls each device of the substrate transport system 1. For example, the controller 15 controls the position and orientation of each movable element 13 in the vacuum transfer chamber 7, the extension and contraction of the substrate support 13a, the opening and closing of the opening and closing door 17, 18, the processing of the semiconductor substrate W in each processing chamber 9, and the like. The arrows shown in FIG. 1 indicate an example of the direction of movement and rotation of the movable element 13. The controller 15 is configured as, for example, a computer. Although not illustrated, the controller 15 may include, for example, a processor such as a CPU, a memory such as a ROM or a RAM, an input device, an output device, a recording device, a communication device, and the like.

### 2. Configuration of stator and movable element

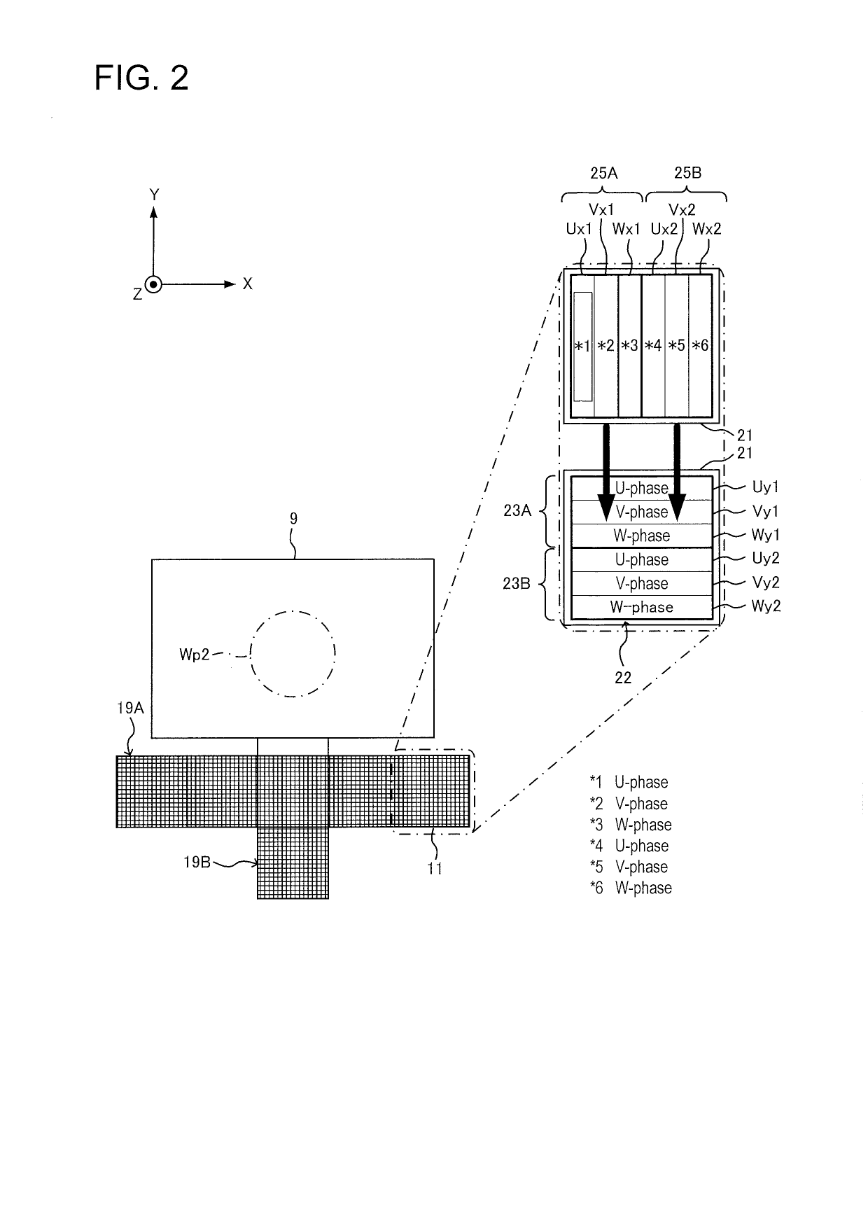

Next, an example of the configuration of the stator 11 and the movable element 13 will be described with reference to FIGS. 2 to 4.

FIG. 2 is a diagram schematically illustrating an example of a coil configuration of the stator 11. As shown in FIG. 2, the stator 11 includes a stator base 21 and a coil unit 22. The coil unit 22 is configured as a coil unit by integrating a plurality of substrate coils. The coil unit 22 is formed in a substantially quadrangular shape (a rectangle or a square) when viewed from the Z-axis direction, and the stator base 21 is formed in a substantially quadrangular shape (a rectangle or a square) larger than the coil unit 22 by a predetermined dimension when viewed from the Z-axis direction. The coil unit 22 includes two sets of first substrate coils 23A and 23B each formed in a substantially rectangular shape with the X-axis direction as a longitudinal direction and including a plurality of substrate coils (three phases of a U-phase, a V-phase, and a W-phase in the example illustrated in FIG. 2) having different phases, and two sets of second substrate coils 25A and 25B each formed in a substantially rectangular shape with the Y-axis direction as a longitudinal direction and including a plurality of substrate coils (three phases of a U-phase, a V-phase, and a W-phase in the example illustrated in FIG. 2) having different phases. The first substrate coil 23A includes a U-phase substrate coil Uy1, a V-phase substrate coil Vy1, and a W-phase substrate coil Wy1. The substrate coils Uy1, Vy1, and Wy1 are each formed in a substantially rectangular shape with a concentrated winding and the X-axis direction as the longitudinal direction, and are arranged adjacent to each other in the Y-axis direction. Similarly, the first substrate coil 23B includes a U-phase substrate coil Uy2, a V-phase substrate coil Vy2, and a W-phase substrate coil Wy2. The substrate coils Uy2, Vy2, and Wy2 are each formed in a substantially rectangular shape with a concentrated winding and the X-axis direction as the longitudinal direction, and are arranged adjacent to each other in the Y-axis direction. The two first substrate coils 23A and 23B are provided adjacent to each other in the Y-axis direction.

The second substrate coil 25A includes a U-phase substrate coil Ux1, a V-phase substrate coil Vx1, and a W-phase substrate coil Wx1. The substrate coils Ux1, Vx1, and Wx1 are each formed in a substantially rectangular shape with a concentrated winding and the Y-axis direction as the longitudinal direction, and are arranged adjacent to each other in the X-axis direction. Similarly, the second substrate coil 25B includes a U-phase substrate coil Ux2, a V-phase substrate coil Vx2, and a W-phase substrate coil Wx2. The substrate coils Ux2, Vx2, and Wx2 are each formed in a substantially rectangular shape with a concentrated winding and the Y-axis direction as the longitudinal direction, and are arranged adjacent to each other in the X-axis direction. The two second substrate coils 25A and 25B are provided adjacent to each other in the X-axis direction.

The coil unit 22 is configured by stacking two first substrate coils 23A and 23B and two second substrate coils 25A and 25B in the Z-axis direction. Although FIG. 2 illustrates a case where the second substrate coils 23A and 23B are stacked on the upper side of the first substrate coils 25A and 25B as an example, the first substrate coils 25A and 25B may be stacked on the upper side of the second substrate coils and. Further, the number of the first substrate coils 23A, 23B and the second substrate coils 25A, 25B is not limited to two sets, respectively, when three phases of the U phase, the V phase, and the W phase are set as one set. For example, one set may be used, or three or more sets may be used. The number of the first substrate coils 23A and 23B and the number of the second substrate coils 25A and 25B are not limited to the same number, and may be different from each other.

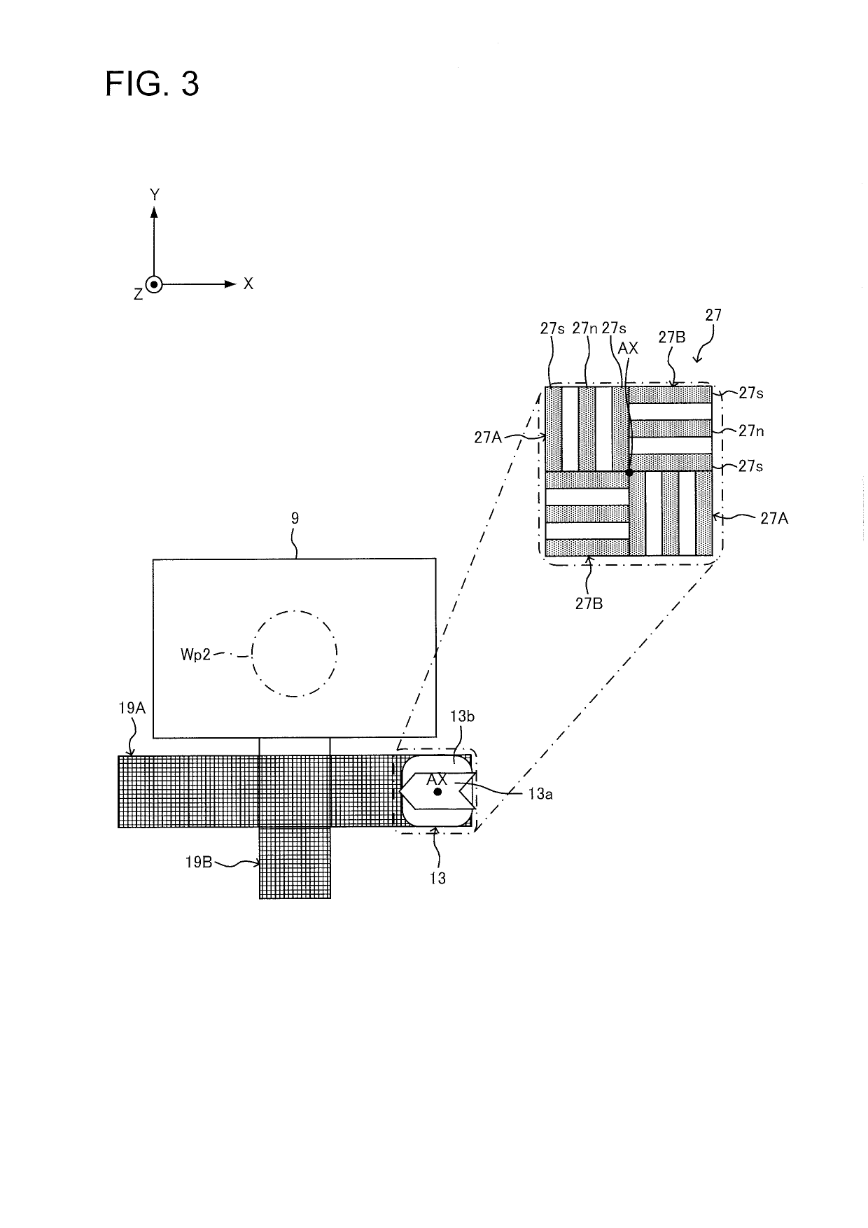

FIG. 3 is a diagram schematically illustrating an example of a magnet configuration of the movable element 13. As shown in FIG. 3, the movable element 13 includes the above-described substrate support 13a and a movable element base 13b. The movable element 13 is formed in a substantially quadrangular shape (a rectangle or a square) when viewed from the Z-axis direction. The movable element 13 has substantially the same dimensions in both the X-axis direction and the Y-axis direction as the stator 11 when viewed from the Z-axis direction. Note that the movable element 13 does not have to be the same size as the stator 11 as long as the movable element 13 and the stator 11 are too large to pass each other on the transport path 19. Further, the movable element 13 may be configured such that the dimension in either one of the X-axis direction and the Y-axis direction is substantially the same as that of the stator 11.

The movable element 13 includes a magnet unit 27 at the movable element base 13b and moves while floating above the stators 11. The magnet unit 27 includes four magnet units 27A and 27B, the four magnet units being constituted by two magnet units 27A and two magnet units 27B. The magnet unit 27A and the magnet unit 27B have different orientations from each other. The magnet unit 27A is elongated in the Y-axis direction, and includes a permanent magnet 27n whose side facing the stator 11 is an N pole, and a permanent magnet 27s whose side facing the stator 11 is an S pole. The magnet unit 27A is configured as a Halbach array in which another permanent magnet is inserted between the permanent magnets 27n and 27s, the magnetization direction of the inserted permanent magnet being orthogonal to the magnetization directions of the permanent magnets 27n and 27s. The magnet unit 27B is elongated in the X-axis direction, and includes a permanent magnet 27n whose side facing the stator 11 is an N pole, and a permanent magnet 27s whose side facing the stator 11 is an S pole. The magnet unit 27B is configured as a Halbach array in which another permanent magnet is inserted between the permanent magnets 27n and 27s, the magnetization direction of the inserted permanent magnet being orthogonal to the magnetization directions of the permanent magnets 27n and 27s. The four magnet units 27A and 27B are alternately arranged so as to surround the rotation axis AX substantially parallel to the Z-axis direction. That is, the two magnet units 27A are arranged point-symmetrically with respect to the rotation axis AX, and the two magnet units 27B are arranged point-symmetrically with respect to the rotation axis AX. The dimensions of the magnet unit 27 in the X-axis direction and the Y-axis direction are substantially the same as those of the coil unit 22 of the stator 11.

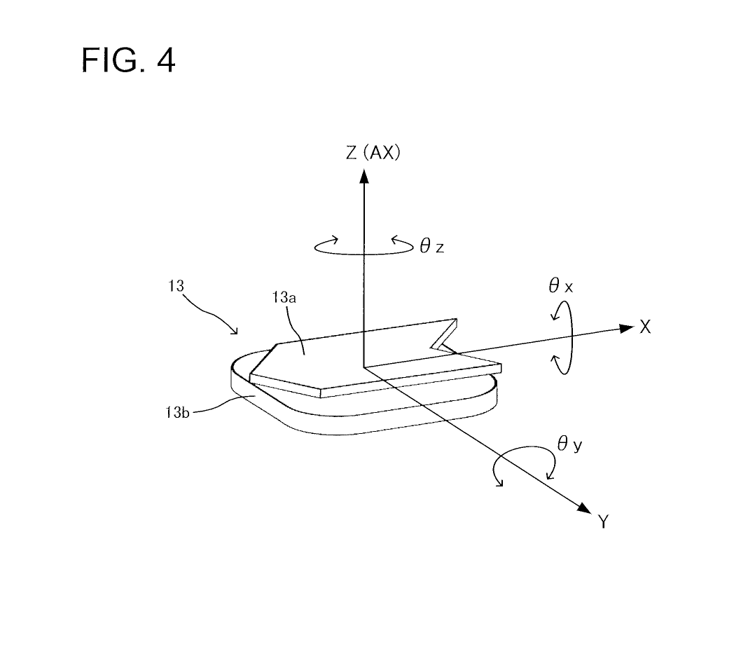

FIG. 4 is a perspective view illustrating an example of the degree of freedom of the operation of the movable element 13 in the planar motor 20 including the stator 11 and the movable element 13. As shown in FIG. 4, the movable element 13 obtains a thrust in the X-axis direction by mutual action of the magnetic field by the second substrate coils 25A and 25B of the stators 11 and the magnetic field by the magnet unit 27A. The movable element 13 obtains a thrust in the Y-axis direction by mutual action of the magnetic field by the first substrate coils 23A and 23B of the stators 11 and the magnetic field by the magnet unit 27B. Further, the movable element 13 obtains a thrust in a rotation direction around the rotation axis AX substantially parallel to the Z-axis direction (vertical direction) by a combination of the thrust in the X-axis direction and the thrust in the Y-axis direction. Thus, the movable element 13 is movable in the horizontal direction (each direction on the XY plane including the X-axis direction and the Y-axis direction) and is rotatable in the θz direction which is the rotation direction around the Z axis (rotation axis AX). That is, the movable element 13 can operate with three degrees of freedom. Further, the movable element 13 obtains a buoyancy in the Z-axis direction by mutual action of the magnetic field by the first substrate coils 23A, 23B and the second substrate coils 25A, 25B and the magnetic field by the magnet units 27A, 27B. Thus, by adjusting the current phases of the first substrate coils 23A and 23B and the second substrate coils 25A and 25B, it is possible to adjust the flying height in the Z-axis direction, the tilt in the θx direction which is the rotation direction around the X-axis, and the tilt in the θy direction which is the rotation direction around the Y-axis. In this case, the movable element 13 can operate with six degrees of freedom.

### Positional relationship between movable element and stator when movable element is rotated

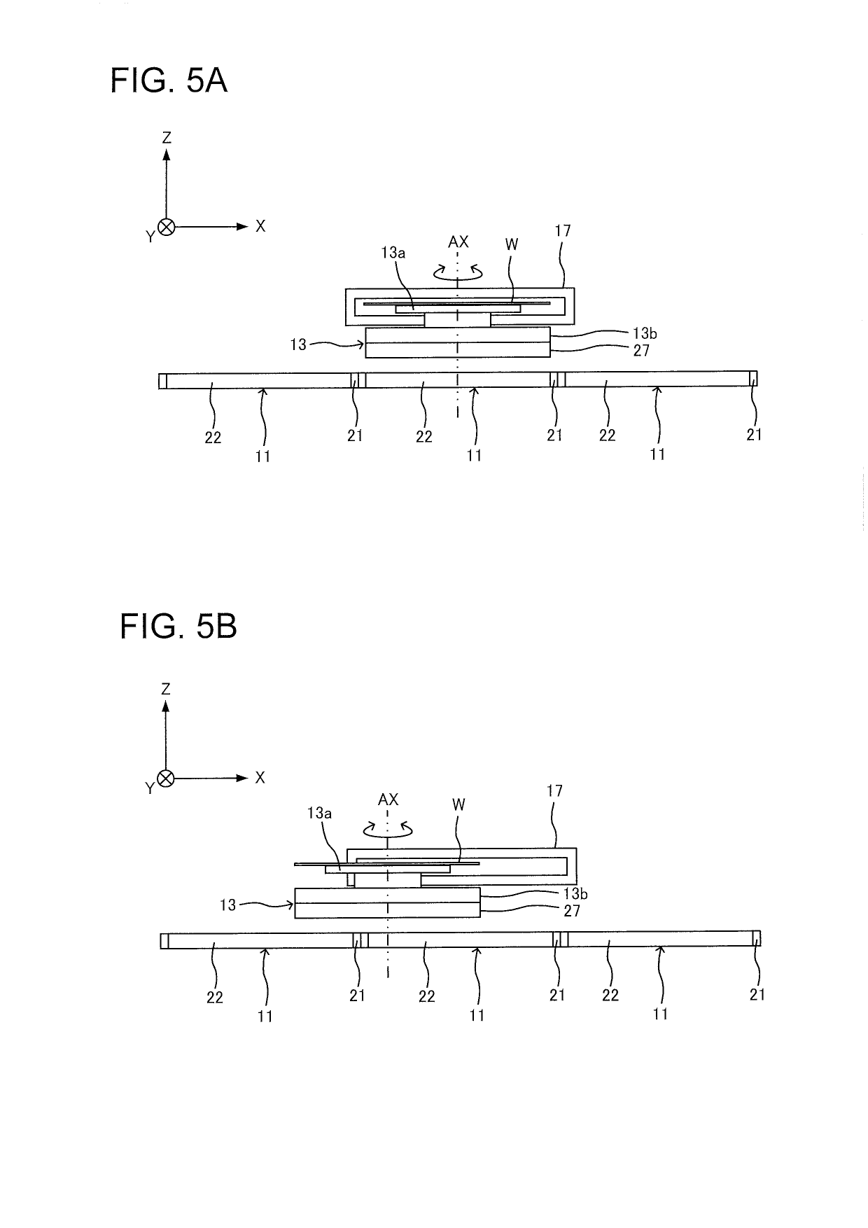

Next, an example of the positional relationship between the movable element 13 and the stator 11 when the movable element 13 is rotated will be described with reference to FIG. 5A and FIG. 5B.

The controller 15 changes the orientation of the movable element 13 so as to change the orientation of the substrate support 13a at a position where at least a part of one of the stators 11 provided in front of the opening/closing door 17, 18 and at least a part of the movable element 13 overlap each other when viewed from the Z-axis direction. The one stator 11 provided in front of the opening/closing door 17 includes not only the stator 11 provided immediately in front of the opening/closing door 17 but also the stator 11 located on an extension line in a direction extending from the opening/closing door 17 in the Y-axis direction. That is, the one stator 11 provided in front of the opening/closing door 17 may be the stator 11 provided immediately in front of the opening/closing door 17, or may be any one of the stators 11 constituting the second transport path 19B in front of the opening/closing door 17. Similarly, the one stator 11 provided in front of the opening/closing door 18 includes not only the stator 11 provided immediately in front of the opening/closing door 18 but also the stator 11 located on the extension line in the direction extending from the opening/closing door 18 in the X-axis direction. That is, the one stator 11 provided in front of the opening/closing door 18 is any one of the stators 11 constituting the first transport path 19A connected to the opening/closing door 18. In addition, the position where at least a part of one stator 11 and at least a part of the movable element 13 overlap each other when viewed from the Z-axis direction is substantially a position where at least a part of the coil unit 22 of one stator 11 and at least a part of the magnet unit 27 of the movable element 13 overlap each other when viewed from the Z-axis direction. Further, the change of the direction of the movable element 13 (the change of the direction of the substrate support 13a) includes a rotation operation with respect to at least one direction of the θx direction, the θy direction, and the θz direction.

For example, the controller 15 rotates the movable element 13 around the rotation axis AX at a position where one stator 11 provided in front of the opening/closing door 17,18 and the rotation axis AX substantially parallel to the Z-axis direction of the movable element 13 overlap each other when viewed from the Z-axis direction.

FIG. 5A schematically illustrates a case where the movable element 13 is rotated about the rotation axis AX at a position where the rotation axis AX of the movable element 13 overlaps with the substantial center of one of the stators 11 provided in front of (for example, immediately in front of) the opening/closing door 17. As shown in FIG. 5A, substantially the entire coil unit 22 of the stator 11 and substantially the entire magnet unit 27 of the movable element 13 face each other in the Z-axis direction. In this case, the controller 15 rotates the movable element 13 around the rotation axis AX by the interaction between the magnetic field by the coil unit 22 of one stator 11 provided in front of the opening/closing door 17 and the magnetic field by the magnet unit 27 of the movable element 13.

FIG. 5B schematically illustrates a case where the movable element 13 is rotated about the rotation axis AX at a position where the rotation axis AX of the movable element 13 is deviated from the center of one of the stators 11 provided in front of (for example, immediately in front of) the opening/closing door 17. As shown in FIG. 5B, a part of the magnet unit 27 of the movable element 13 faces a part of the coil unit 22 of one of the stators 11 provided in front of the opening/closing door 17 in the Z-axis direction, and the remaining part of the magnet unit 27 of the movable element 13 faces a part of the coil unit 22 of the adjacent one of the stators 11 provided in front of the opening/closing door 17 in the Z-axis direction. In this case, the controller 15 rotates the movable element 13 around the rotation axis AX by the interaction between the magnetic field by the coil unit 22 of one stator 11 provided in front of the opening/closing door 17 and the coil unit 22 of the stator 11 adjacent to the one stator 11 and the magnetic field by the magnet unit 27 of the movable element 13. Note that the movable element 13 may be rotated about the rotation axis AX at a position where the rotation axis AX of the movable element 13 overlaps the middle (boundary) between one stator 11 provided in front of the opening/closing door 17 and the adjacent stator 11.

Although the case where the movable element 13 is rotated about the rotation axis AX in front of the opening/closing door 17 of the processing chamber 9 has been described with reference to FIGS. 5A and 5B, the same applies to the case where the movable element 13 is rotated about the rotation axis AX in front of the opening/closing door 18 of the load lock chamber 5.

In the present embodiment, the controller 15 rotates the movable element 13 around the rotation axis AX at a position where at least a part of one of the stators 11 in the first transport path 19A or the second transport path 19B and at least a part of the movable element 13 overlap each other when viewed from the Z-axis direction. At this time, the controller 15 may rotate the movable element 13 around the rotation axis AX at a position where at least a part of one of the stators 11 in the second transport path 19B and at least a part of the movable element 13 overlap each other when viewed from the Z-axis direction. At this time, the controller 15 may rotate the movable element 13 around the rotation axis AX at a position where at least a part of one of the stators 11 in the second transport path 19B and at least a part of the movable element 13 overlap each other when viewed from the Z-axis direction.

### 4. Specific example of operation of movable element by control of controller

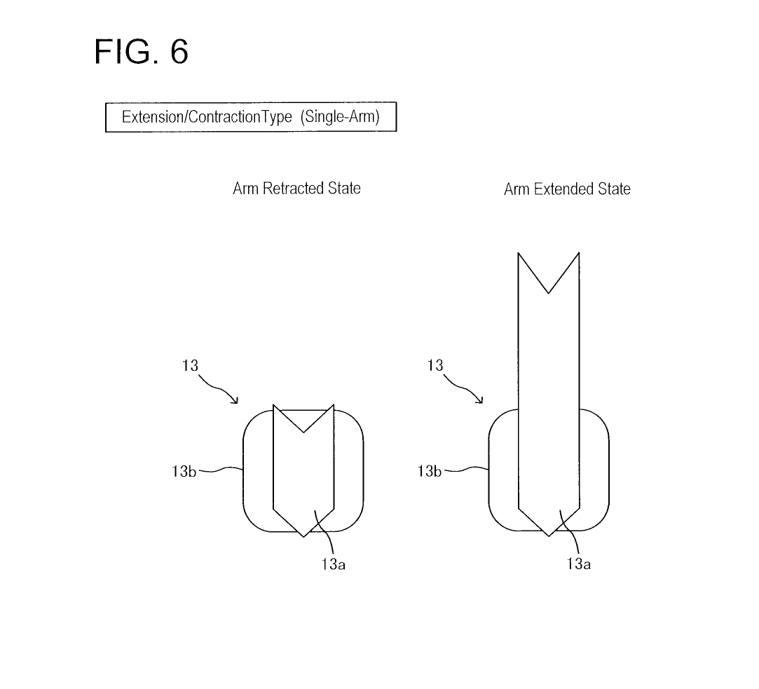

Next, a specific example of the operation of the movable element 13 under the control of the controller 15 will be described with reference to FIGS. 6 to 15. In the following description, the six processing chambers 9 are referred to as processing chambers 9 (1), 9 (2), 9 (3), 9 (4), 9 (5), and 9 (6) to be distinguished from each other, and the two load lock chambers 5 are referred to as load lock chambers 5 (1) and 5 (2) to be distinguished from each other.

### 4-1. Case where substrate support is single-arm telescopic type

First, an operation example in a case where the movable element 13 includes the substrate support 13a which is a single-arm telescopic arm will be described. FIG. 6 is a diagram schematically illustrating an extension/contraction operation of the substrate support 13a, which is a single-arm extension/contraction type arm. As shown in FIG. 6, the substrate support 13a includes an extension/contraction mechanism (not illustrated), and expands and contracts in a specific direction (for example, forward) from the movable element 13. The substrate support 13a is retracted so as to be substantially accommodated in the movable element base 13b in the arm retracted state, and is extended by a predetermined length in front of the movable element 13 in the arm extended state. The predetermined length is a length that allows the tip of the substrate support 13a to reach the mounting table Wp2 of the processing chamber 9 or the mounting table Wp2 of the load lock chamber 5 in a state where the movable element 13 is located on the stator 11 immediately before the opening/closing door 17, 18.

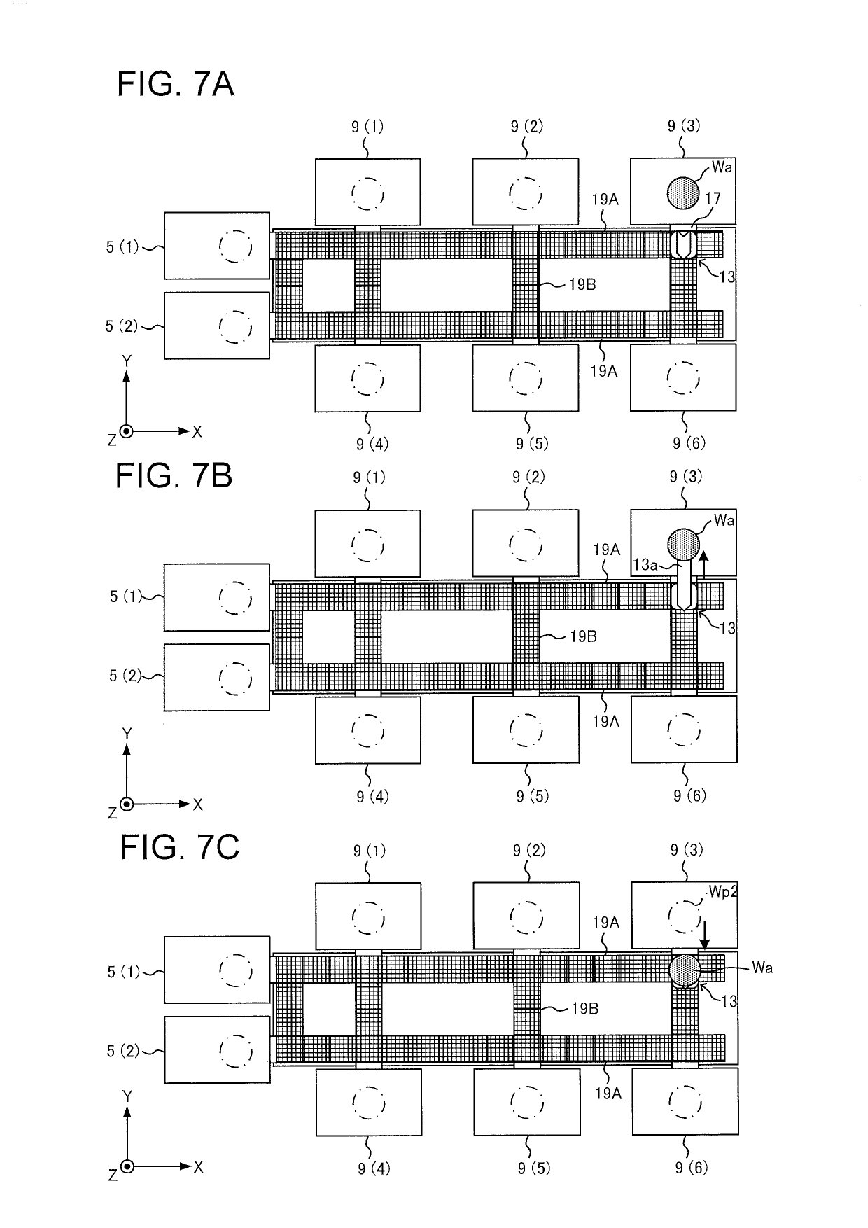

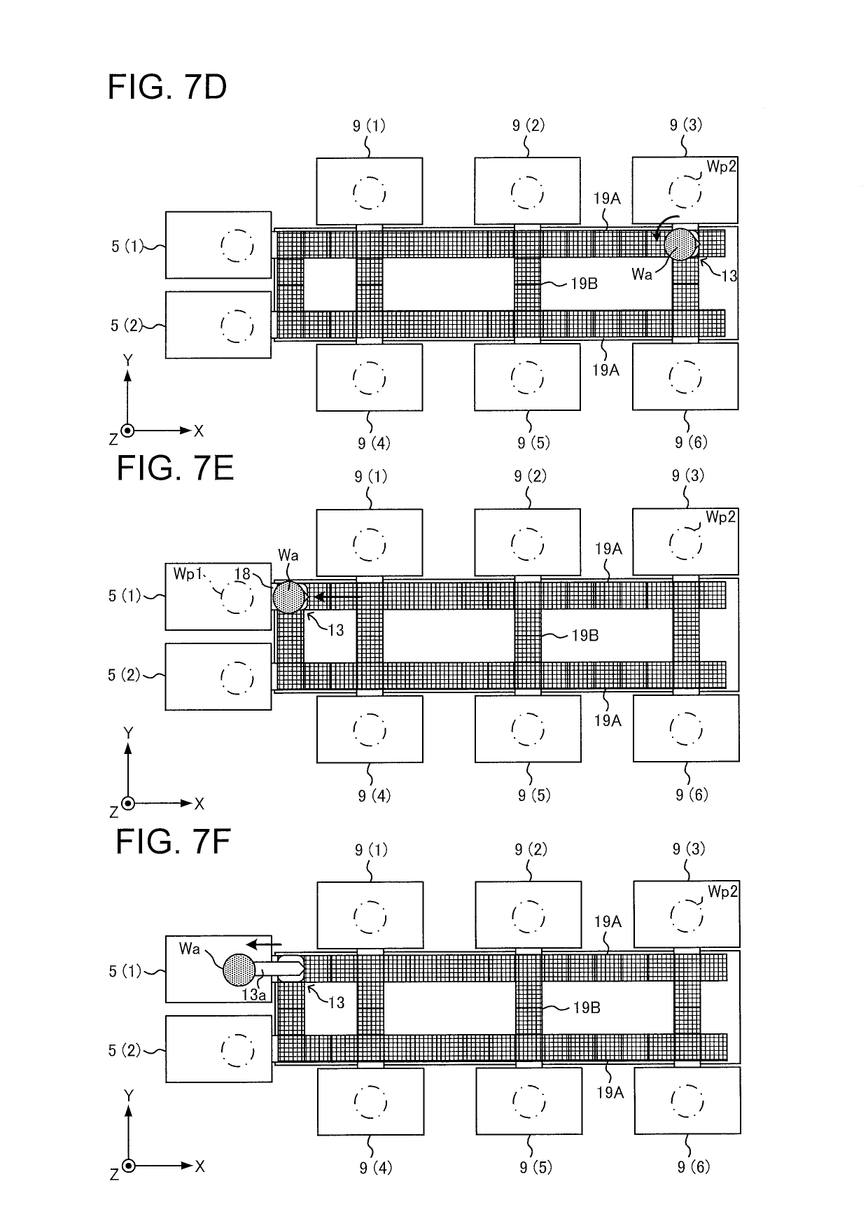

FIGS. 7A to 7F are diagrams illustrating an operation example in a case where the movable element 13 including the single-arm substrate support 13a transports the processed semiconductor substrate Wa from the processing chamber 9 (3) to the load lock chamber 5 (1). First, as shown in FIG. 7A, the movable element 13 moves to a position above the stator 11 immediately before the opening/closing door 17 of the processing chamber 9 (3), that is, a position facing the opening/closing door 17 of the processing chamber 9 (3).

Next, as shown in FIG. 7B, the movable element 13 extends the substrate support 13a into the processing chamber 9 (3) through the opened opening/closing door 17, and receives the processed semiconductor substrate Wa placed on the placement table Wp2 of the processing chamber 9 (3). The semiconductor substrate Wa is received by, for example, the lifting operation of the movable element 13 in the Z-axis direction, the rotating operation of the movable element 13 in the θx direction, or a lifter pin (not illustrated) included in the processing chamber 9 (3).

Next, as shown in FIG. 7C, the movable element 13 retracts the substrate support 13a, and carries the semiconductor substrate Wa out of the processing chamber 9 (3).

Next, as shown in FIG. 7D, the movable element 13 rotates approximately 90° in the counterclockwise direction on the stator 11 immediately before the opening/closing door 17 of the processing chamber 9 (3), and changes the direction of the substrate support 13a from the processing chamber 9 (3) side to the load lock chamber 5 (1) side.

Next, as shown in FIG. 7E, the movable element 13 moves on the first transport path 19A to a position above the stator 11 immediately before the opening/closing door 18 of the load lock chamber 5 (1), that is, a position facing the opening/closing door 18 of the load lock chamber 5 (1).

Next, as shown in the FIG. 7F, the movable element 13 extends the substrate support 13a into the load lock chamber 5 (1) through the opened opening/closing door 18, and delivers the processed semiconductor substrate Wa to the mounting table Wp1 of the load lock chamber 5 (1). The semiconductor substrate Wa is transferred by, for example, the lifting operation of the movable element 13 in the Z-axis direction, the rotation operation of the movable element 13 in the θy direction, or a lifter pin (not illustrated) provided in the load lock chamber 5 (1).

Although the semiconductor substrate Wa is transferred from the processing chamber 9 (3) to the load lock chamber 5 (1) in the above description, the same operation as described above may be performed when the processed semiconductor substrate Wa is transferred from the processing chamber 9 (1) or the processing chamber 9 (2) to the load lock chamber 5 (1). Further, when the processed semiconductor substrate Wa is transferred from any of the processing chambers 9 (4), 9 (5), and 9 (6) to the load lock chamber 5 (2), the same operation as described above may be performed. In contrast to the above, when the unprocessed semiconductor substrate Wb is transferred from the load lock chamber 5 (1) to any of the processing chambers 9 (1), 9 (2), and 9 (3), or when the unprocessed semiconductor substrate Wb is transferred from the load lock chamber 5 (2) to any of the processing chambers 9 (4), 9 (5), and 9 (6), the above operation may be performed in reverse.

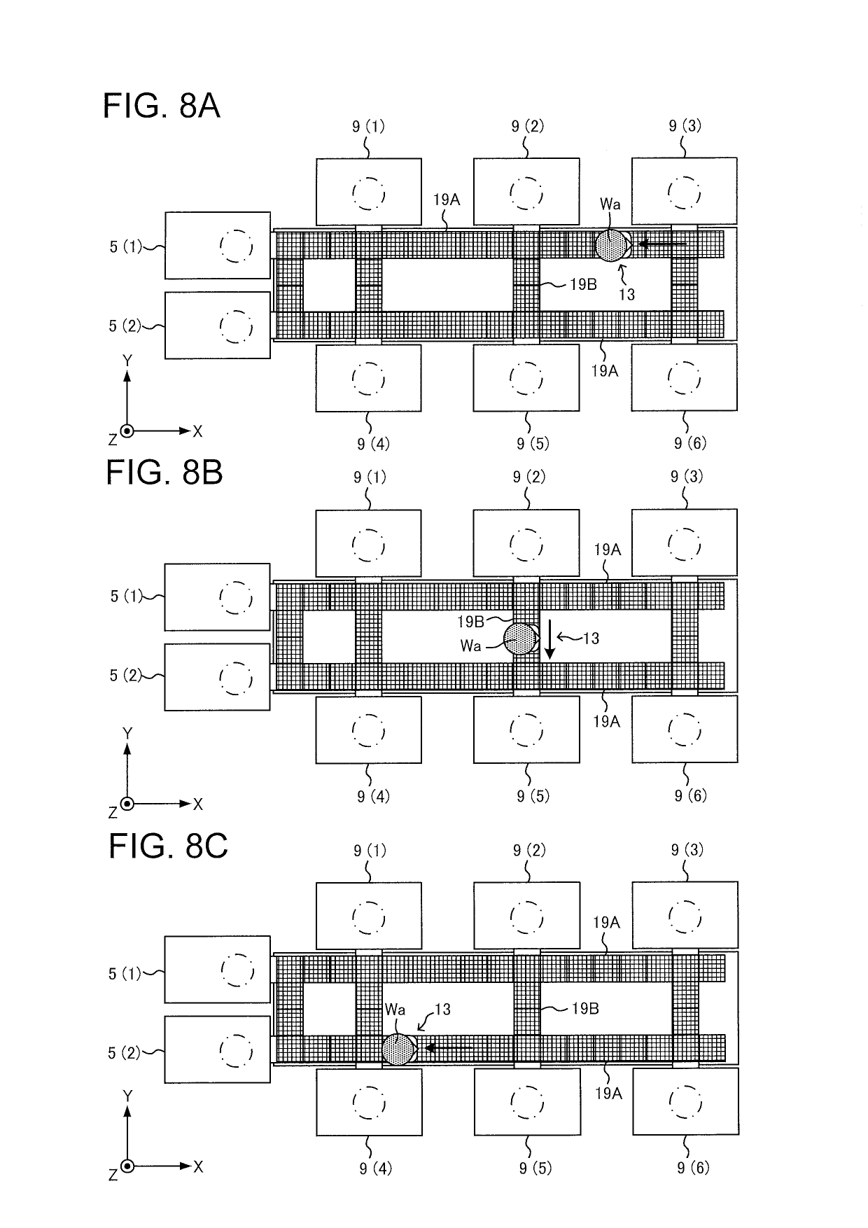

When the processed semiconductor substrate Wa is transferred from the processing chamber 9 (3) to the load lock chamber 5 (2), the semiconductor substrate Wa passes through one of the second transport paths 19B and moves onto the other first transport path 19A in the movement of the first transport path 19A shown in FIG. 7E. FIGS. 8A to 8C are diagrams illustrating a part of an operation example in a case where the movable element 13 including the single-arm telescopic substrate support 13a transports the processed semiconductor substrate Wa from the processing chamber 9 (3) to the load lock chamber 5 (2) through the second transport path 19B.

First, the same operation as that of the above-described FIGS. 7A to 7D is performed. Next, as shown in the FIG. 8A, the movable element 13 moves on the first transport path 19A on the positive side in the Y-axis direction toward the load lock chamber 5 (1).

Next, as shown in FIG. 8B, the movable element 13 moves in the same direction as when moving on the first transport path 19A, for example, on the second transport path 19B in front of the processing chamber 9 (2) toward the Y-axis negative side.

Next, as shown in the FIG. 8C, the movable element 13 moves on the first transport path 19A on the negative side in the Y-axis direction toward the load lock chamber 5 (2) in the same direction as when moving on the second transport path 19B. Thereafter, the movable element 13 moves to a position facing the opening/closing door 18 of the load lock chamber 5 (2), and performs the same operations as those in the above-described FIG. 7E and 7F.

In this manner, the controller 15 moves the movable element 13 so that the orientation of the substrate support 13a when moving on the first transport path 19A and the orientation of the substrate support 13a when moving on the second transport path 13a are the same.

In the above description, it is conveyed through the second transport path 19B located in front of the processing chamber 9(2), however, it may alternatively be conveyed through any of the other second transport paths 19B. Further, when the processed semiconductor substrate Wa is transferred from the processing chamber 9 (1) or the processing chamber 9 (2) to the load lock chamber 5 (2), the same operation as described above may be performed. Further, when the processed semiconductor substrate Wa is transferred from any one of the processing chambers 9 (4), 9 (5), and 9 (6) to the load lock chamber 5 (1), the same operation as described above may be performed. In contrast to the above, when the unprocessed semiconductor substrate Wb is transferred from the load lock chamber 5 (2) to any of the processing chambers 9 (1), 9 (2), and 9 (3), or when the unprocessed semiconductor substrate Wb is transferred from the load lock chamber 5 (1) to any of the processing chambers 9 (4), 9 (5), and 9 (6), the above operation may be performed in reverse.

### 4-2. Case where substrate support is double-arm telescopic type

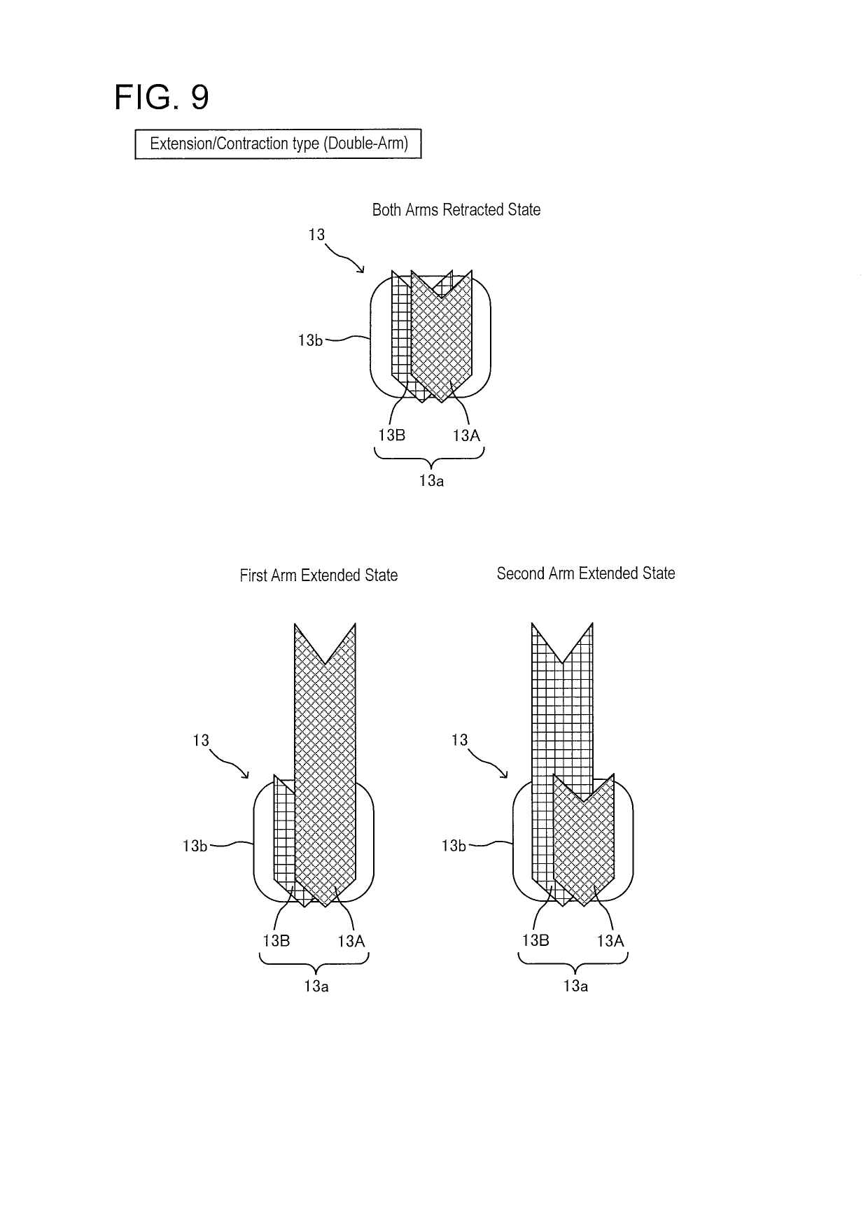

Next, an operation example in a case where the movable element 13 includes the substrate support 13a which is a double-arm telescopic arm will be described. FIG. 9 is a diagram schematically illustrating an extension/contraction operation of the substrate support 13a, which is a double-arm extension/contraction type arm. As shown in FIG. 9, the substrate support 13a has two arms 13A and 13B each having an extension mechanism (not illustrated). The first arm 13A and the second arm 13B are installed at different heights in the height direction (Z-axis direction). In the example shown in FIG. 9, the first arm 13A is installed above the second arm 13B, but the opposite may be adopted. The first arm 13A and the second arm 13B each extend and retract in a specific direction (e.g., forward) from the movable element 13. The first arm 13A and the second arm 13b are respectively retracted so as to be substantially accommodated in the movable element base 13b in the arm retracted state, and are extended by a predetermined length in front of the movable element 13 in the arm extended state. The predetermined length is a length that allows the tip of the first arm 13A or the second arm 13B to reach the mounting table Wp2 of the processing chamber 9 or the mounting table Wp1 of the load lock chamber 5 in a state where the movable element 13 is located on the stator 11 immediately before the opening/closing door 17, 18.

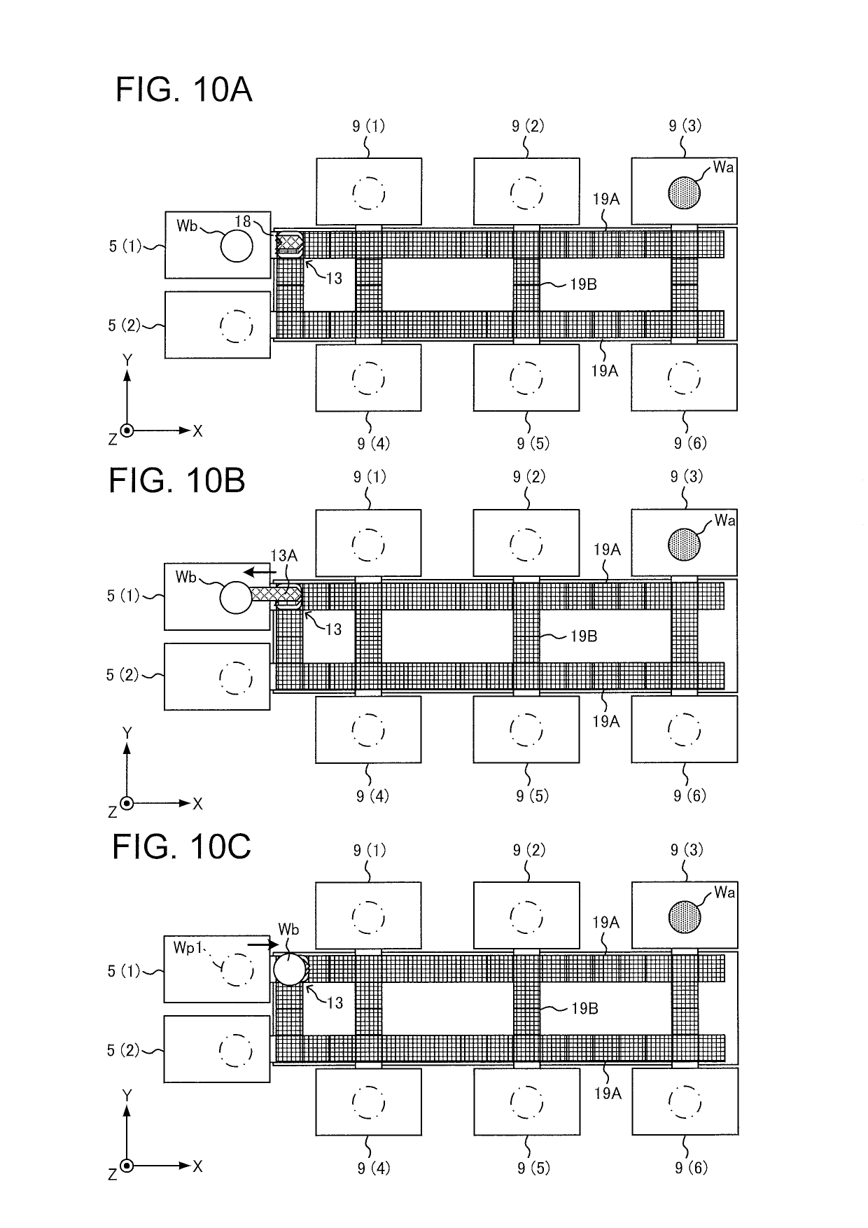

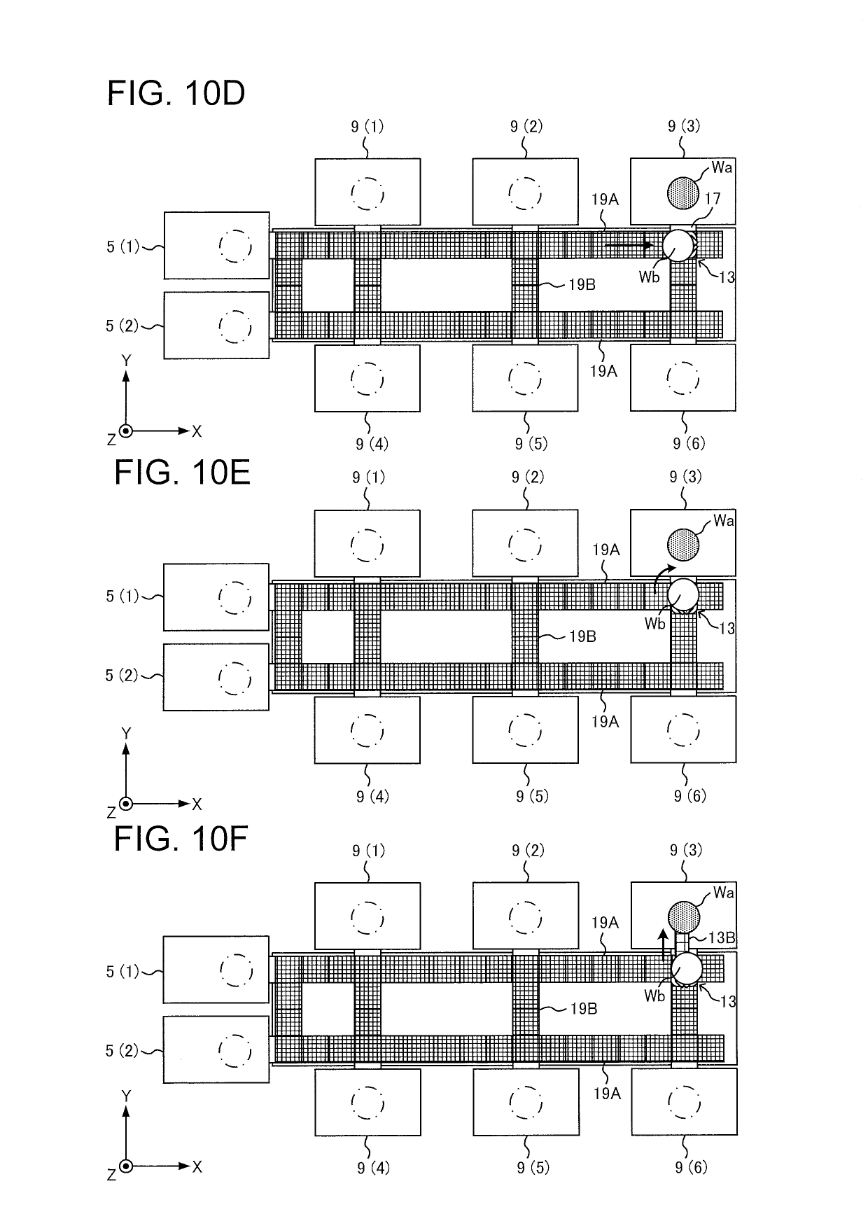

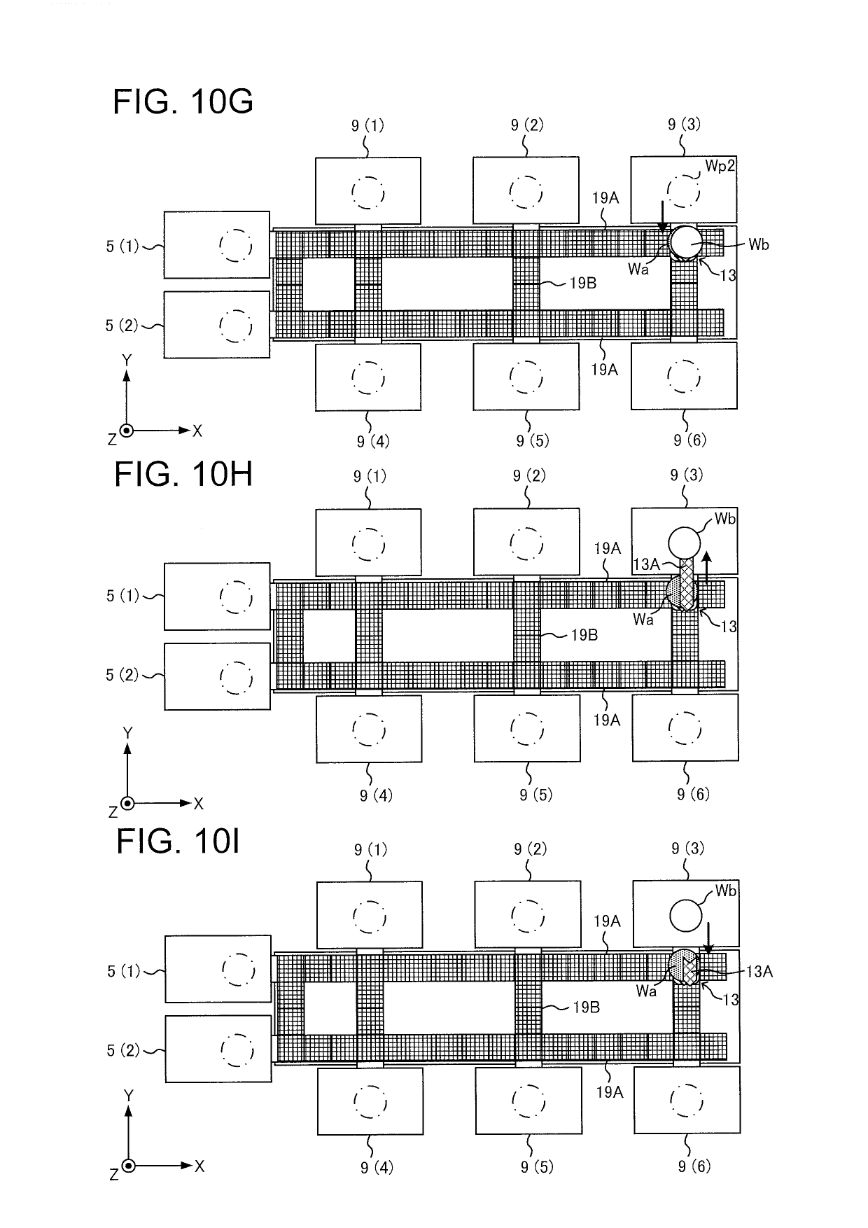

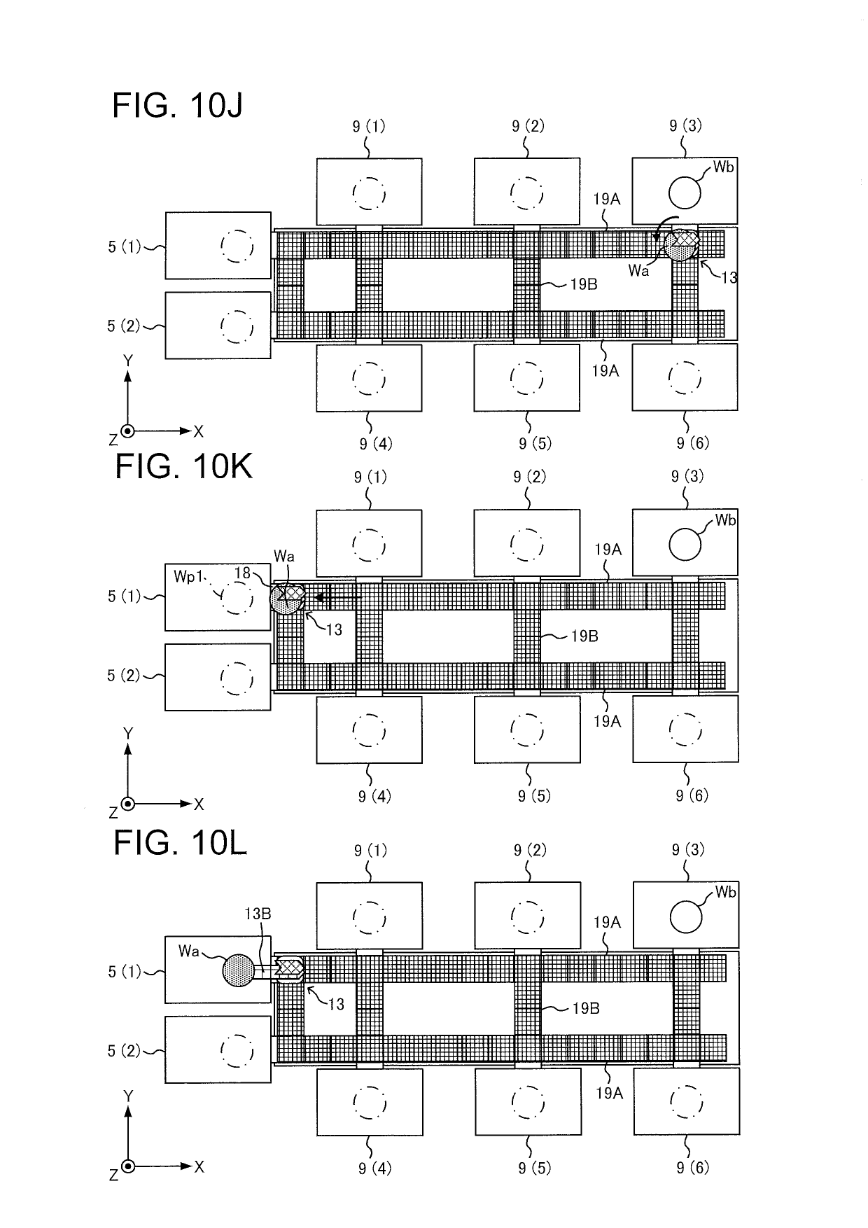

FIGS. 10A to 10L are diagrams illustrating an operation example in a case where the movable element 13 including the double-arm telescopic substrate support 13a transports the unprocessed semiconductor substrate Wb from the load lock chamber 5 (1) to the processing chamber 9 (3) and transports the processed semiconductor substrate Wa from the processing chamber 9 (3) to the load lock chamber 5 (1). Next, as shown in FIG. 7E, the movable element 13 moves on the first transport path 19A to a position above the stator 11 immediately before the opening/closing door 18 of the load lock chamber 5 (1), that is, a position facing the opening/closing door 18 of the load lock chamber 5 (1).

Next, as shown in the FIG. 10B, the movable element 13 extends the first arm 13A of the substrate support 13a into the load lock chamber 5 (1) through the opened opening/closing door 18, and receives the unprocessed semiconductor substrate Wb placed on the setting base Wp1 of the load lock chamber 5 (1). The semiconductor substrate Wb is received by, for example, the lifting operation of the movable element 13 in the Z-axis direction, the rotating operation of the movable element 13 in the θy direction, or a lifter pin (not illustrated) provided in the load lock chamber 5 (1).

Next, as shown in FIG. 10C, the movable element 13 retracts the first arm 13A, and carries the semiconductor substrate Wb out of the load lock chamber 5 (1).

Next, as shown in the FIG. 10D, the movable element 13 moves on the first transport path 19A to a position above the stator 11 immediately before the opening/closing door 17 of the processing chamber 9 (3), that is, a position facing the opening/closing door 17 of the processing chamber 9 (3), without changing the direction of the substrate support 13a.

Next, as shown in FIG. 10E, the movable element 13 rotates approximately 90° in the clockwise direction on the stator 11 immediately before the opening/closing door 17 of the processing chamber 9 (3), and changes the direction of the substrate support 13a from the load lock chamber 5 (1) side to the processing chamber 9 (3) side.

Next, as shown in FIG. 10F, the movable element 13 extends the second arm 13B of the substrate support 13a into the processing chamber 9 (3) through the opened opening/closing door 17, and receives the processed semiconductor substrate Wa placed on the setting base Wp2 of the processing chamber 9 (3). The semiconductor substrate Wa is received by, for example, the lifting operation of the movable element 13 in the Z-axis direction, the rotating operation of the movable element 13 in the θx direction, or a lifter pin (not illustrated) included in the processing chamber 9 (3).

Next, as shown in FIG. 10G, the movable element 13 retracts the substrate support 13a, and carries the semiconductor substrate Wa out of the processing chamber 9 (3).

Next, as shown in FIG. 10H, the movable element 13 extends the first arm 13A of the substrate support 13a into the processing chamber 9 (3) through the opened opening/closing door 17, and delivers the unprocessed semiconductor substrate Wb to the setting base Wp2 of the processing chamber 9 (3). The semiconductor substrate Wb is transferred by, for example, the lifting operation of the movable element 13 in the Z-axis direction, the rotating operation of the movable element 13 in the θx direction, or a lifter pin (not illustrated) provided in the processing chamber 9 (3).

Next, as shown in FIG. 10I, the movable element 13 retracts the first arm 13A. As a result, the movable element 13 is in a state in which the semiconductor substrate Wa is mounted on the second arm 13B.

Next, as shown in the FIG. 10J, the movable element 13 rotates approximately 90° in the counterclockwise direction on the stator 11 immediately before the opening/closing door 17 of the processing chamber 9 (3), and changes the direction of the substrate support 13a from the processing chamber 9 (3) side to the load lock chamber 5 (1) side.

Next, as shown in the FIG. 10K, the movable element 13 moves on the first transport path 19A to a position above the stator 11 immediately before the opening/closing door 18 of the load lock chamber 5 (1), that is, a position facing the opening/closing door 18 of the load lock chamber 5 (1).

Next, as shown in the FIG. 10L, the movable element 13 extends the second arm 13B into the load lock chamber 5 (1) through the opened opening/closing door 18, and delivers the processed semiconductor substrate Wa to the setting base Wp1 of the load lock chamber 5 (1). The semiconductor substrate Wa is transferred by, for example, the lifting operation of the movable element 13 in the Z-axis direction, the rotation operation of the movable element 13 in the θy direction, or a lifter pin (not illustrated) provided in the load lock chamber 5 (1).

Although the semiconductor substrate W is carried in and out between the load lock chamber 5 (1) and the processing chamber 9 (3) in the above description, the same operation as described above may be performed when the semiconductor substrate W is carried in and out between the load lock chamber 5 (1) and the processing chamber 9 (1) or the processing chamber 9 (2). Further, when the semiconductor substrate W is carried in and out between the load lock chamber 5 (2) and any one of the processing chambers 9 (4), 9 (5), and 9 (6), the same operation as described above may be performed. When the substrate W is transferred between the load lock chamber 5 (1) and one of the processing chambers 9 (4), 9 (5), and 9 (6), the substrate W passes through one of the second transport paths 19B and moves onto the other first transport path 19A in the movement of the first transport path 19A shown in the above FIGS. 10D and 10K, and the same operation is performed. The same applies to the case where the semiconductor substrate W is carried in and out between the load lock chamber 5 (2) and any one of the processing chambers 9 (1), 9 (2), and 9 (3).

### 4-3. Case where substrate support is single-arm non-extendable type

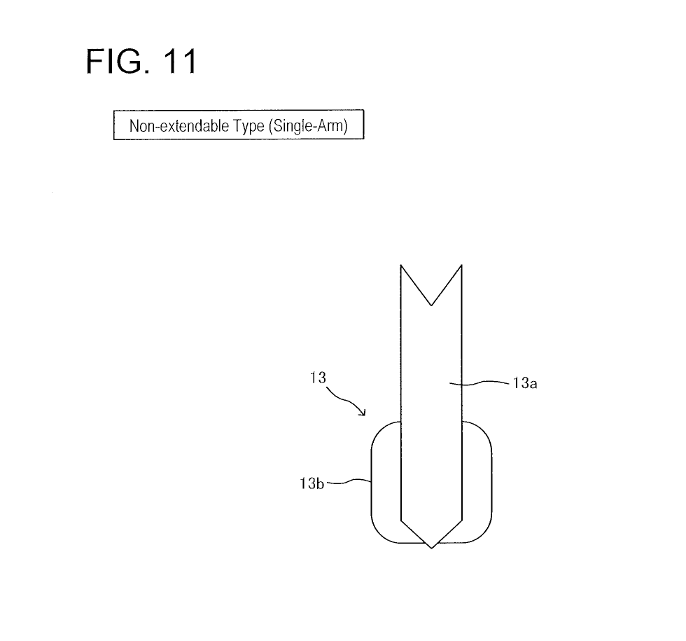

Next, an operation example in a case where the movable element 13 includes the substrate support 13a which is a single-arm non-extendable arm will be described. FIG. 11 is a diagram schematically illustrating a configuration of the substrate support 13a which is a single-arm non-extendable arm. As shown in FIG. 11, the substrate support 13a does not include an extension/contraction mechanism and has a constant length. The length of the substrate support 13a is set to a length that allows the tip of the substrate support 13a to reach the setting base Wp2 of the processing chamber 9 or the setting base Wp1 of the load lock chamber 5 in a state where the movable element 13 is located on the stator 11 immediately before the opening/closing door 17, 18.

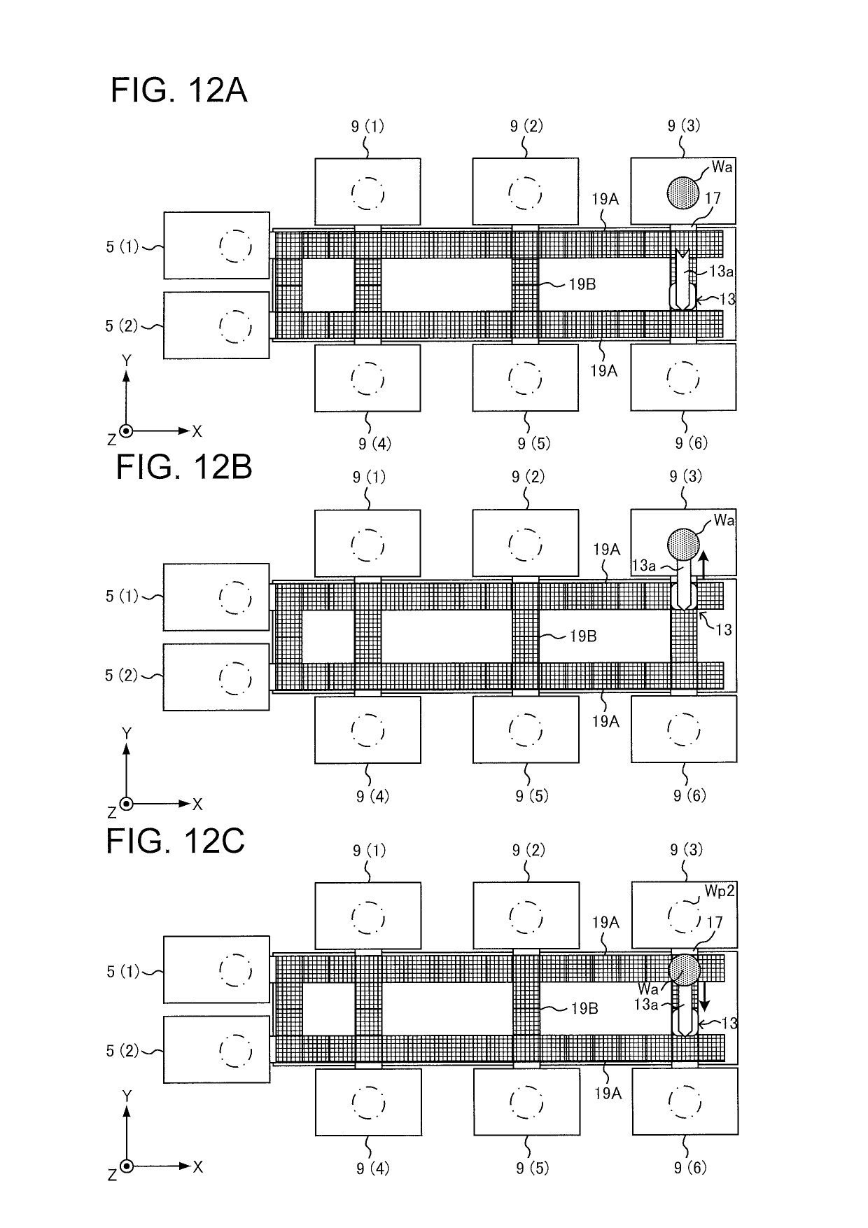

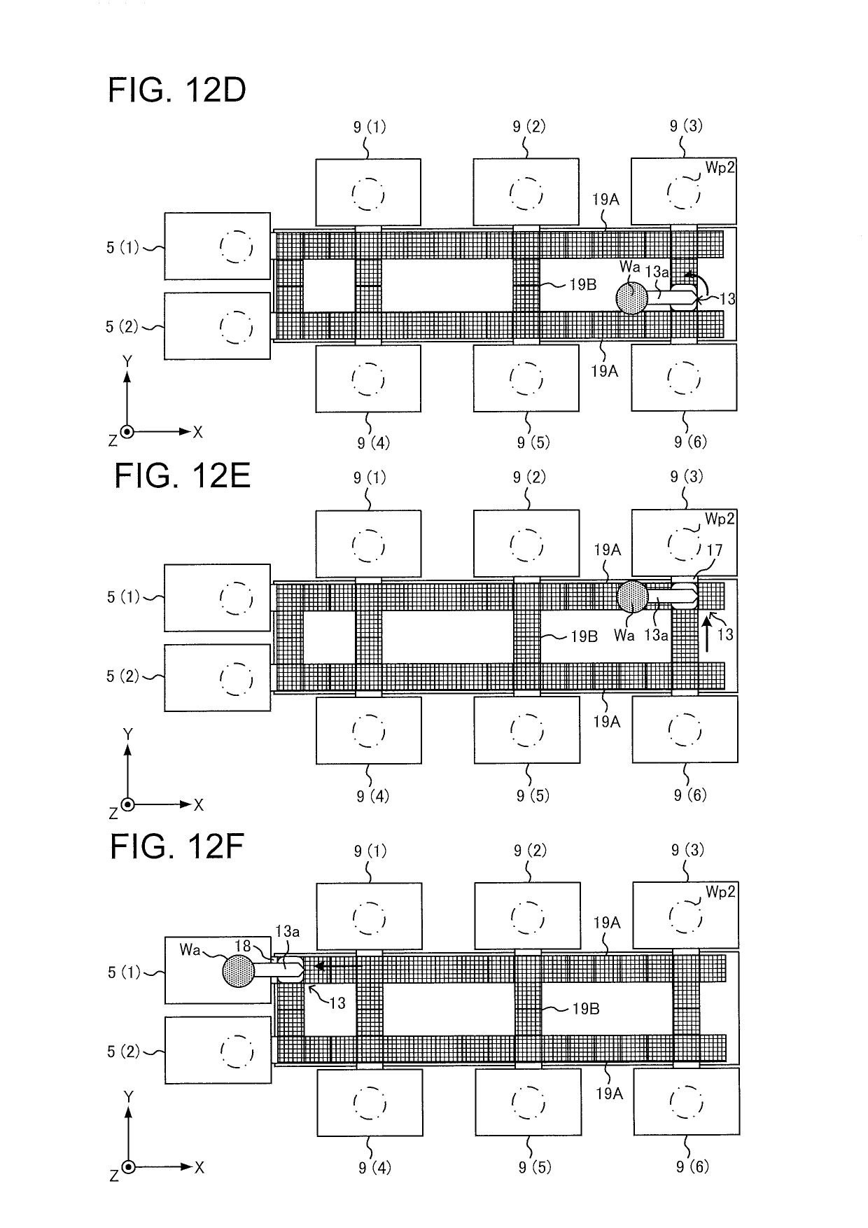

FIGS. 12A to 12F are diagrams illustrating an operation example in a case where the movable element 13 including the single-arm non-extendable substrate support 13a transports the processed semiconductor substrate Wa from the processing chamber 9 (3) to the load lock chamber 5 (1). First, as shown in FIG. 12A, the movable element 13 moves to a position above the predetermined stator 11 in the second transport path 13a in front of the opening/closing door 17 of the processing chamber 9 (3) so that the tip of the substrate support 13a does not interfere with the opening/closing door 17 of the processing chamber 9 (3).

Next, as shown in FIG. 12B, the movable element 13 moves to a position above the stator 11 immediately before the opening/closing door 17 of the processing chamber 9 (3), that is, a position facing the opening/closing door 17 of the processing chamber 9 (3). Accordingly, the movable element 13 allows the substrate support 13a to enter the processing chamber 9 (3) through the opened opening/closing door 17, and receives the processed semiconductor substrate Wa placed on the setting base Wp2 of the processing chamber 9 (3). The semiconductor substrate Wa is received by, for example, the lifting operation of the movable element 13 in the Z-axis direction, the rotating operation of the movable element 13 in the θx direction, or a lifter pin (not illustrated) included in the processing chamber 9 (3).

Next, as shown in the FIG. 12C, the movable element 13 moves to a position above a predetermined stator 11 in the second transport path 19B and separates from the opening/closing door 17, and the semiconductor substrate Wa is carried out from the processing chamber 9 (3).

Next, as shown in FIG. 12D, the movable element 13 rotates approximately 90° in the counterclockwise direction on the stator 11 of the second transport path 19B, and changes the direction of the substrate support 13a from the processing chamber 9 (3) side to the negative side in the X-axis direction.

Next, as shown in FIG. 12E, the movable element 13 moves on the second transport path 19B to a position above the stator 11 immediately before the opening/closing door 17 of the processing chamber 9 (3), that is, a position facing the opening/closing door 17 of the processing chamber 9 (3).

Next, as shown in FIG. 12F, the movable element 13 moves on the first transport path 19A to a position above the stator 11 immediately before the opening/closing door 18 of the load lock chamber 5 (1), that is, a position facing the opening/closing door 18 of the load lock chamber 5 (1). Accordingly, the movable element 13 moves the substrate support 13a into the load lock chamber 5 (1) through the opened opening/closing door 18, and transfers the processed semiconductor substrate Wa to the setting base Wp1 of the load lock chamber 5 (1). The semiconductor substrate Wa is transferred by, for example, the lifting operation of the movable element 13 in the Z-axis direction, the rotation operation of the movable element 13 in the θy direction, or a lifter pin (not illustrated) provided in the load lock chamber 5 (1).

Although the semiconductor substrate Wa is transferred from the processing chamber 9 (3) to the load lock chamber 5 (1) in the above description, the same operation as described above may be performed when the processed semiconductor substrate Wa is transferred from the processing chamber 9 (1) or the processing chamber 9 (2) to the load lock chamber 5 (1). Further, when the processed semiconductor substrate Wa is transferred from any of the processing chambers 9 (4), 9 (5), and 9 (6) to the load lock chamber 5 (2), the same operation as described above may be performed. In contrast to the above, when the unprocessed semiconductor substrate Wb is transferred from the load lock chamber 5 (1) to any of the processing chambers 9 (1), 9 (2), and 9 (3), or when the unprocessed semiconductor substrate Wb is transferred from the load lock chamber 5 (2) to any of the processing chambers 9 (4), 9 (5), and 9 (6), the above operation may be performed in reverse.

When the processed semiconductor substrate Wa is transferred from any one of the processing chambers 9 (1), 9 (2), and 9 (3) to the load lock chamber 5 (2), the semiconductor substrate Wa passes through any one of the second transport paths 19B and moves onto the other first transport path 19A in the movement of the first transport path 19A shown in FIG. 12F, and the same operation may be performed. The same applies to the case where the processed semiconductor substrate Wa is transferred from any of the processing chambers 9 (4), 9 (5), and 9 (6) to the load lock chamber 5 (1).

### 4-4. Case where substrate support is double-arm non-extendable type

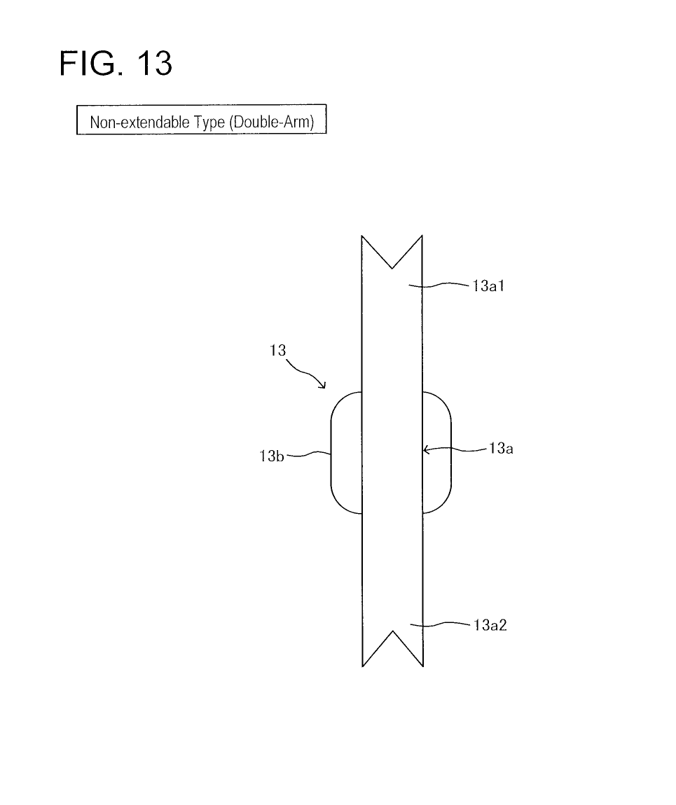

Next, an operation example in a case where the movable element 13 includes the substrate support 13a which is a double-arm non-extendable arm will be described. FIG. 13 is a diagram schematically illustrating a configuration of the substrate support 13a which is a double-arm non-extendable arm. As shown in FIG. 13, the substrate support 13a does not include an extension/contraction mechanism and has a constant length. The substrate support 13a has two arm portions 13a1 and 13a2 at both ends. The first arm 13a1 extends from the movable element 13 in a first direction (e.g., forward), and the second arm 13a2 extends from the movable element 13 in a second direction (e.g., backward) opposite to the first direction. The first arm 13a1 and the second arm 13a2 each protrude from the movable element 13 by a predetermined length. The predetermined length is a length that allows the tip of the first arm 13a1 or the second arm 13a2 to reach the setting base Wp2 of the processing chamber 9 or the setting base Wp1 of the load lock chamber 5 in a state where the movable element 13 is located on the stator 11 immediately before the opening/closing door 17, 18.

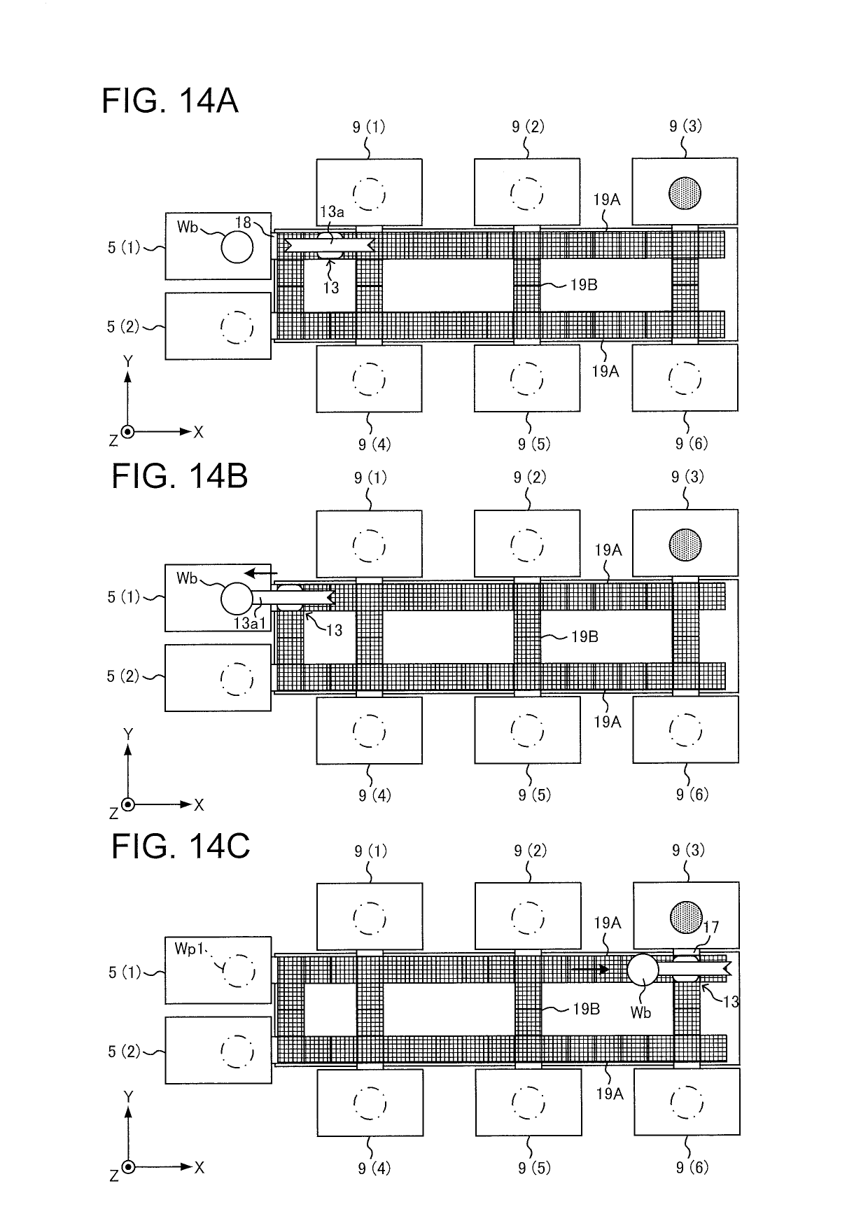

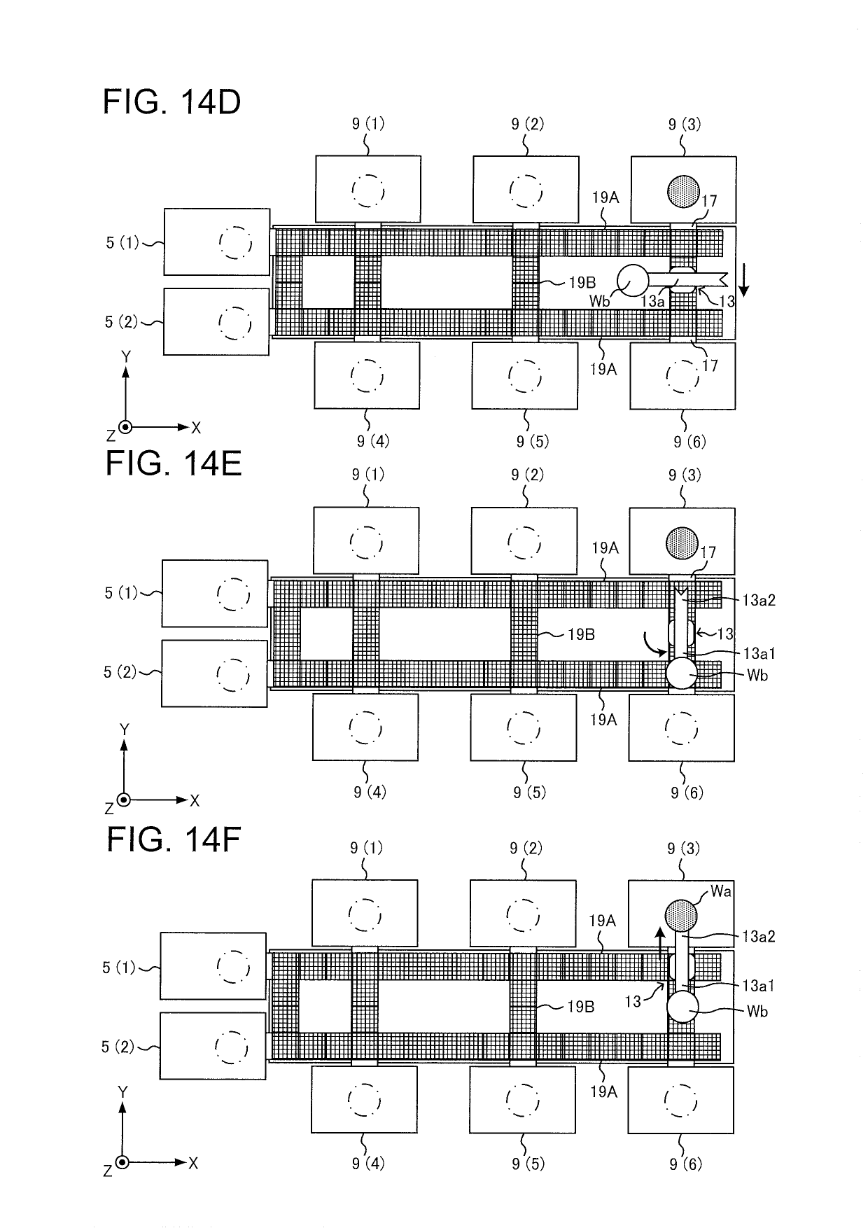

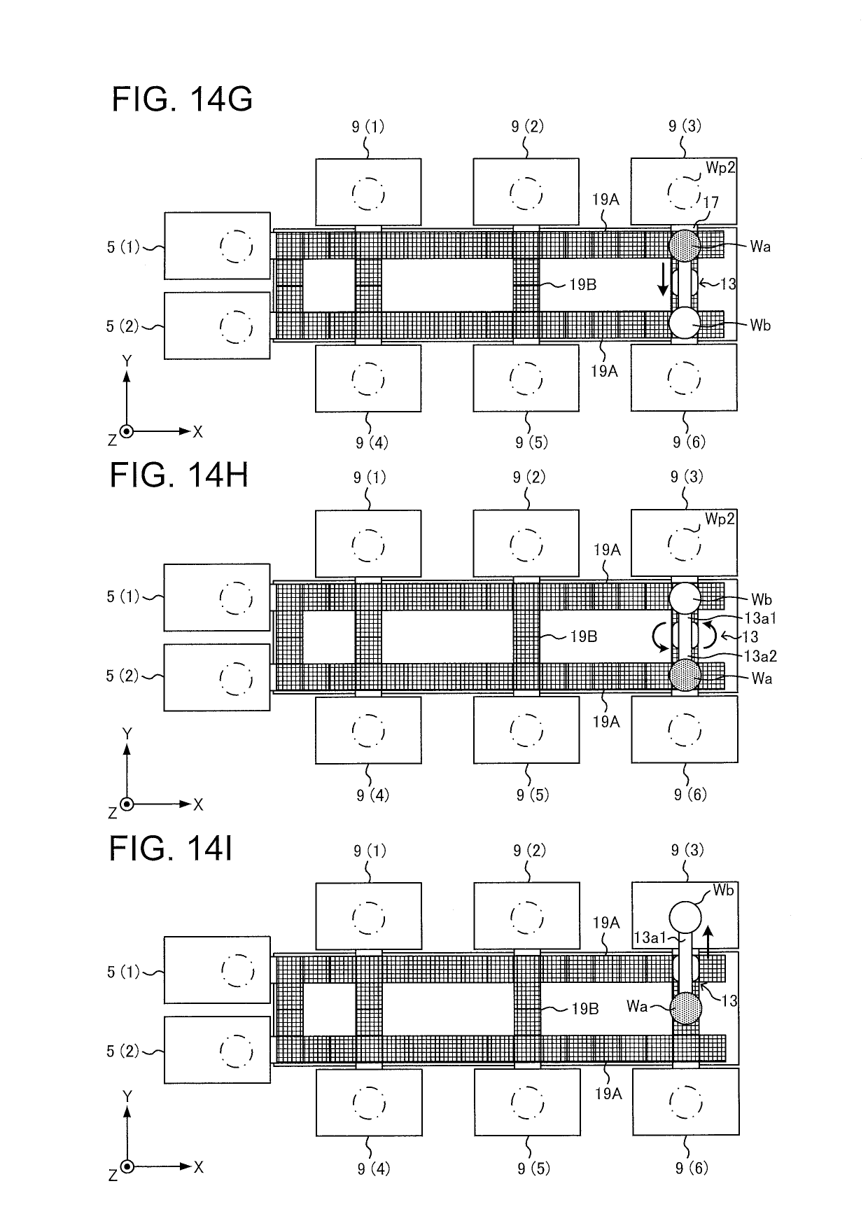

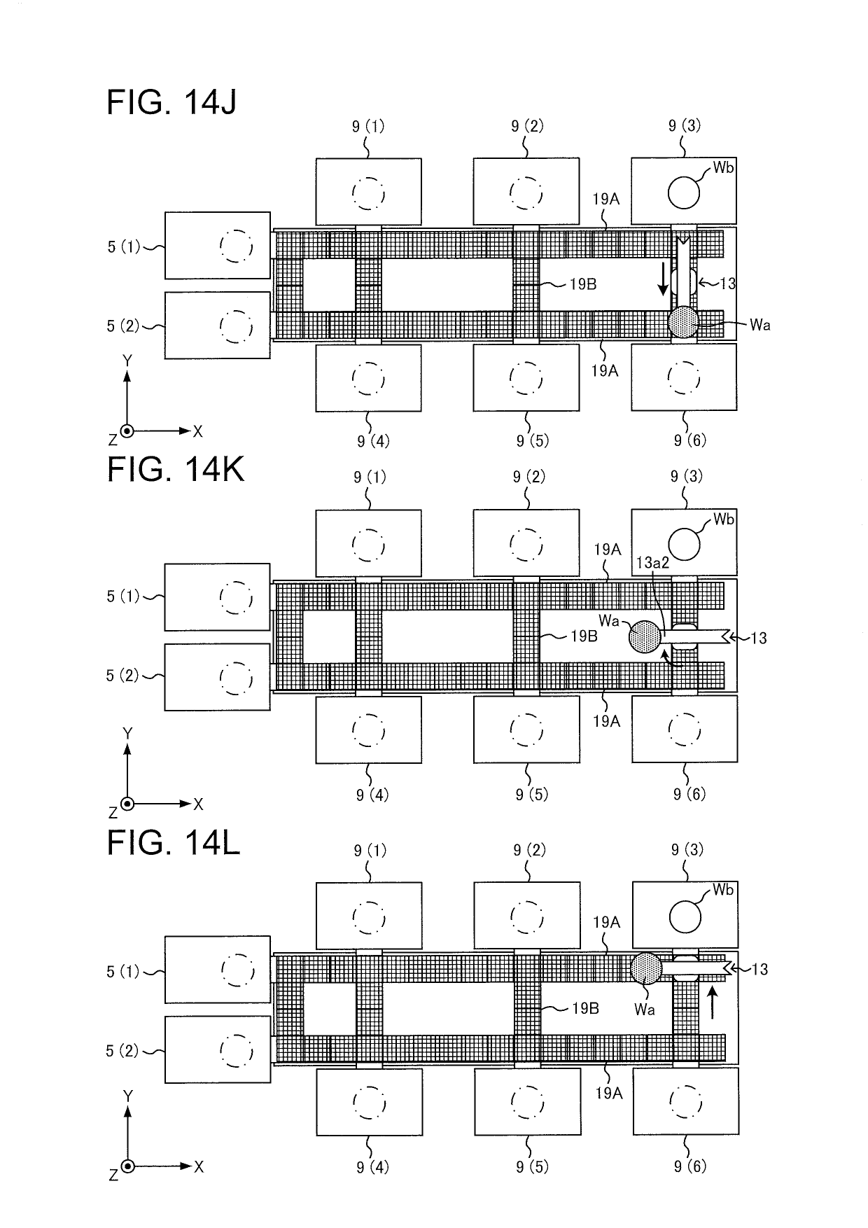

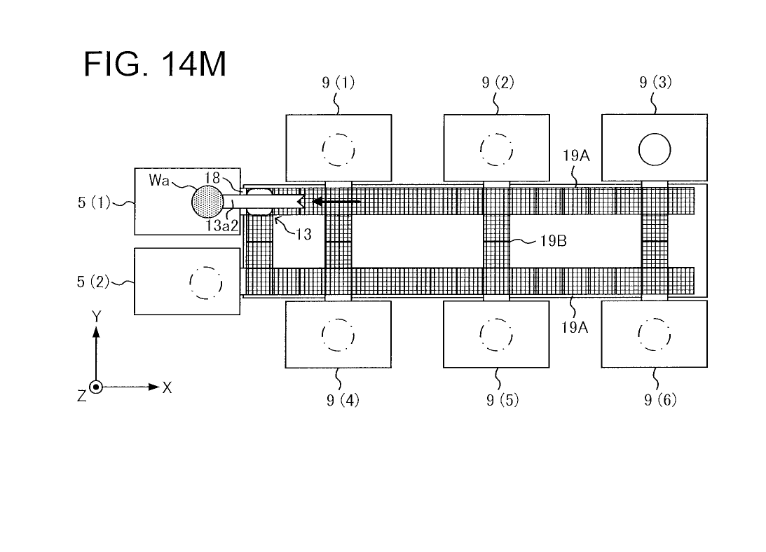

FIGS. 14A to 14M are diagrams illustrating an operation example in a case where the movable element 13 including the double-arm non-extendable substrate support 13a transports the unprocessed semiconductor substrate Wb from the load lock chamber 5 (1) to the processing chamber 9 (3) and transports the processed semiconductor substrate Wa from the processing chamber 9 (3) to the load lock chamber 5 (1). First, as shown in FIG. 14A, the movable element 13 moves to a position above a predetermined stator 11 in the first transport path 19A in front of the opening/closing door 18 of the load lock chamber 5 (1) so that the tip of the substrate support 13a does not interfere with the opening/closing door 18 of the load lock chamber 5 (1).

Next, as shown in FIG. 14B, the movable element 13 moves to a position above the stator 11 immediately before the opening/closing door 18 of the load lock chamber 5 (1), that is, a position facing the opening/closing door 18 of the load lock chamber 5 (1). As a result, the movable element 13 causes the first arm 13a1 of the substrate support 13a1 to enter the load lock chamber 5 (1) through the opened opening/closing door 18, and receives the unprocessed semiconductor substrate Wb placed on the setting base Wp1 of the load lock chamber 5 (1). The semiconductor substrate Wb is received by, for example, the lifting operation of the movable element 13 in the Z-axis direction, the rotating operation of the movable element 13 in the θy direction, or a lifter pin (not illustrated) provided in the load lock chamber 5 (1).

Next, as shown in FIG. 14C, the movable element 13 carries the semiconductor substrate Wb out of the load lock chamber 5 (1), and moves on the first transport path 19A to a position above the stator 11 immediately before the opening/closing door 17 of the processing chamber 9 (3), that is, a position facing the opening/closing door 17 of the processing chamber 9 (3), without changing the orientation of the substrate support 13a.

Next, as shown in FIG. 14D, the movable element 13 moves to a position above a predetermined stator 11 in the second transport path 13a without changing the orientation of the substrate support 13a. This position is a position where both ends of the substrate support 13a and the mounted semiconductor substrate Wb do not interfere with the opening/closing doors 17 of the processing chambers 9 (3) and 9 (6) when the substrate support 13a is rotated.

Next, as shown in FIG. 14E, the movable element 13 rotates approximately 90° in the counterclockwise direction on the stator 11 of the second transport path 19B, and changes the direction of the first arm 13a1 on which the semiconductor substrate Wb is mounted from the negative side in the X-axis direction to the processing chamber 9 (6) side, and changes the direction of the second arm 13a2 from the positive side in the X-axis direction to the processing chamber 9 (3) side.

Next, as shown in FIG. 14F, the movable element 13 moves on the second transport path 19B to a position above the stator 11 immediately before the opening/closing door 17 of the processing chamber 9 (3), that is, a position facing the opening/closing door 17 of the processing chamber 9 (3). Accordingly, the movable element 13 allows the second arm 13a2 of the substrate support 13a to enter the processing chamber 9 (3) through the opened opening/closing door 17, and receives the processed semiconductor substrate Wa placed on the setting base Wp2 of the processing chamber 9 (3). The semiconductor substrate Wa is received by, for example, the lifting operation of the movable element 13 in the Z-axis direction, the rotating operation of the movable element 13 in the θx direction, or a lifter pin (not illustrated) included in the processing chamber 9 (3).

Next, as shown in FIG. 14G, the movable element 13 moves to a position above a predetermined stator 11 in the second transport path 19B and separates from the opening/closing door 17, and the semiconductor substrate Wa is carried out from the processing chamber 9 (3). The positions are positions where both ends of the substrate support 13a and the mounted semiconductor substrates Wa and Wb do not interfere with the opening/closing doors 17 of the processing chambers 9 (3) and 9 (6) when the substrate support 13a is rotated.

Next, as shown in FIG. 14H, the movable element 13 rotates approximately 180° in the clockwise direction or the counterclockwise direction on the stator 11 of the second transport path 19B. Accordingly, the direction of the first arm 13a1 on which the semiconductor substrate Wb is mounted is changed from the processing chamber 9 (6) side to the processing chamber 9 (3) side, and the direction of the second arm 13a2 on which the semiconductor substrate Wa is mounted is changed from the processing chamber 9 (3) side to the processing chamber 9 (6) side.

Next, as shown in FIG. 14I, the movable element 13 moves on the second transport path 19B to a position above the stator 11 immediately before the opening/closing door 17 of the processing chamber 9 (3), that is, a position facing the opening/closing door 17 of the processing chamber 9 (3). Thus, the movable element 13 causes the first arm 13a1 of the substrate support 13a to enter the processing chamber 9 (3) through the opened opening/closing door 17, and transfers the unprocessed semiconductor substrate Wb to the setting base Wp2 of the processing chamber 9 (3). The semiconductor substrate Wb is transferred by, for example, the lifting operation of the movable element 13 in the Z-axis direction, the rotating operation of the movable element 13 in the θx direction, or a lifter pin (not illustrated) provided in the processing chamber 9 (3).

Next, as shown in FIG. 14J, the movable element 13 moves to a position above a predetermined stator 11 in the second transport path 19B and separates from the opening/closing door 17. This position is a position where both ends of the substrate support 13a and the mounted semiconductor substrate Wa do not interfere with the opening/closing door 17 of the processing chambers 9 (3) and 9 (6) when the substrate support 13a is rotated.

Next, as shown in FIG. 14K, the movable element 13 rotates clockwise by about 90° on the stator 11 of the second transport path 19B, and changes the direction of the second arm 13a2 on which the semiconductor substrate Wa is mounted from the processing chamber 9 (6) side to the negative side in the X-axis direction.

Next, as shown in FIG. 14L, the movable element 13 moves on the second transport path 19B to a position above the stator 11 immediately before the opening/closing door 17 of the processing chamber 9 (3), that is, a position facing the opening/closing door 17 of the processing chamber 9 (3).

Next, as shown in FIG. 14M, the movable element 13 moves on the first transport path 19A to a position above the stator 11 immediately before the opening/closing door 18 of the load lock chamber 5 (1), that is, a position facing the opening/closing door 18 of the load lock chamber 5 (1). Accordingly, the movable element 13 allows the second arm 13a2 of the substrate support 13a to enter the load lock chamber 5 (1) through the opened opening/closing door 18, and delivers the processed semiconductor substrate Wa to the setting base Wp1 of the load lock chamber 5 (1). The semiconductor substrate Wa is transferred by, for example, the lifting operation of the movable element 13 in the Z-axis direction, the rotation operation of the movable element 13 in the θy direction, or a lifter pin (not illustrated) provided in the load lock chamber 5 (1).

Although the semiconductor substrate W is carried in and out between the load lock chamber 5 (1) and the processing chamber 9 (3) in the above description, the same operation as described above may be performed when the semiconductor substrate W is carried in and out between the load lock chamber 5 (1) and the processing chamber 9 (1) or the processing chamber 9 (2). Further, when the semiconductor substrate W is carried in and out between the load lock chamber 5 (2) and any one of the processing chambers 9 (4), 9 (5), and 9 (6), the same operation as described above may be performed. When the substrate W is transferred between the load lock chamber 5 (1) and one of the processing chambers 9 (4), 9 (5), and 9 (6), the substrate W passes through one of the second transport paths 19B and moves onto the other first transport path 19A in the movement of the first transport path 19A shown in the above FIGS. 5 (14C) and 5 (14K), and the same operation is performed. The same applies to the case where the semiconductor substrate W is carried in and out between the load lock chamber 5 (2) and any one of the processing chambers 9 (1), 9 (2), and 9 (3).

### 4-5. Position adjustment operation of substrate by movable element

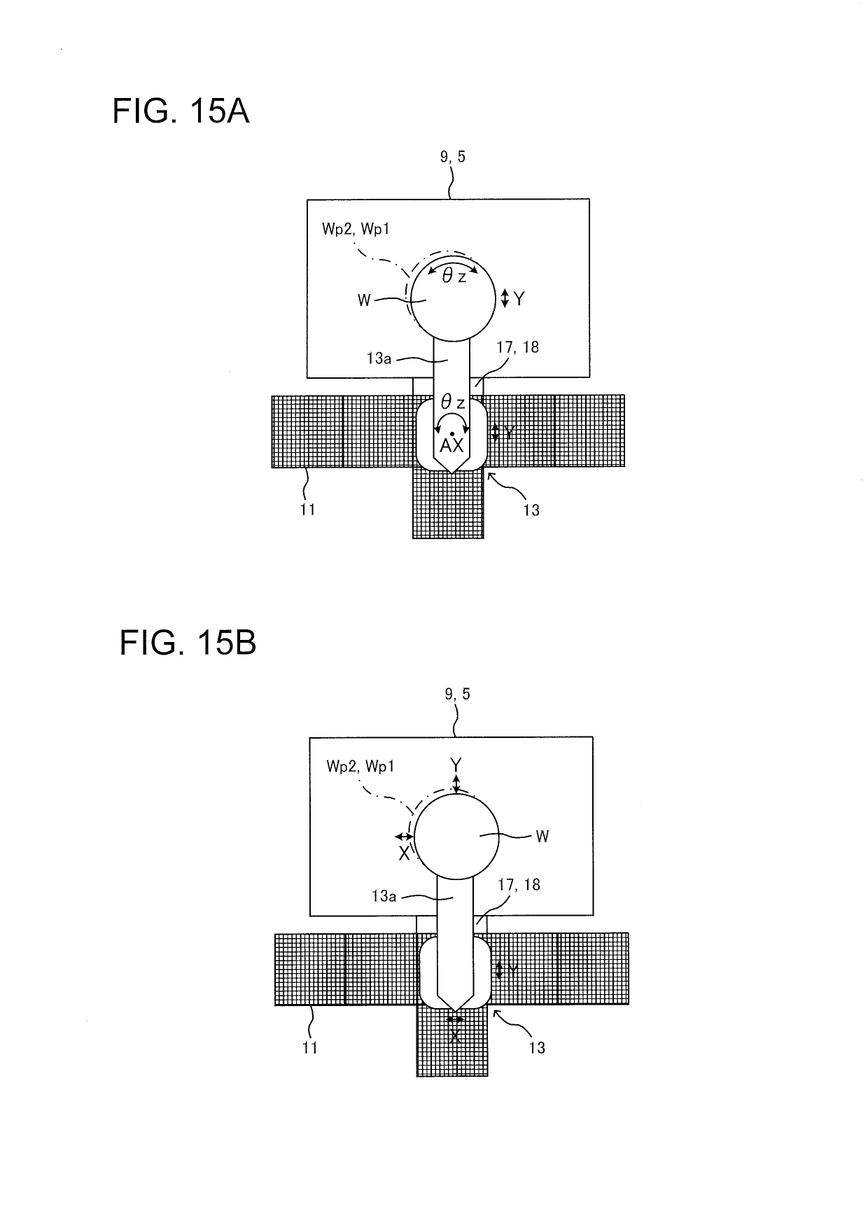

Next, the position adjustment operation of the semiconductor substrate W by the movable element 13 will be described. FIG. 15A schematically shows an example of the position adjustment operation of the semiconductor substrate W by the movable element 13. FIG. 15B schematically illustrates another example of the position adjustment operation of the semiconductor substrate W by the movable element 13.

The controller 15 adjusts at least one of the position and the direction of the movable element 13 so that the position of the semiconductor substrate W becomes the position of the setting base Wp2 (an example of a predetermined position) in the processing chamber 9 at a position where at least a part of one of the stators 11 provided immediately before the opening/closing door 17 of the processing chamber 9 and at least a part of the movable element 13 overlap each other. Similarly, the controller 15 adjusts at least one of the position and the direction of the movable element 13 so that the position of the semiconductor substrate W becomes the position of the Wp1 of the setting base (an example of the predetermined position) in the load lock chamber 5 at the position where at least a part of one of the stators 11 provided immediately before the opening/closing door 18 of the load lock chamber 5 and at least a part of the movable element 13 overlap each other.

For example, in the example shown in FIG. 15A, the movable element 13 performs at least one of the horizontal operation in the Y-axis direction and the rotational operation in the θz direction around the rotation axis AX, thereby adjusting or correcting the position of the semiconductor substrate W mounted on the tip of the substrate support 13a. In the example shown in FIG. 15B, the movable element 13 performs at least one of the horizontal operation in the X-axis direction and the horizontal operation in the Y-axis direction, thereby adjusting or correcting the position of the semiconductor substrate W mounted on the tip of the substrate support 13a.

### Effects of Embodiment

As described above, in the substrate transport system 1 of the present embodiment, the direction of the movable element 13 is changed in front of the processing chamber 9 or the load lock chamber 5 to change the direction of the substrate support 13a, and the semiconductor substrate W supported by the substrate support 13a is carried into and out of the processing chamber 9 or the load lock chamber 5. Thus, the movable element 13 can be moved while minimizing the change in the direction of the movable element 13, so that the tact time can be shortened and the efficiency of conveying the semiconductor substrate W can be improved.

In the present embodiment, the controller 15 may rotate the movable element 13 about the rotation axis AX at a position where one stator 11 provided in front of the opening/closing door 17,18 and the rotation axis AX of the movable element 13 overlap each other when viewed from the Z-axis direction. In this case, as long as the rotation axis AX of the movable element 13 is at a position overlapping with one stator 11 provided in front of the opening/closing door 17,18, the movable element 13 and the stator 11 can be rotated even if they do not completely overlap with each other. This improves the degree of freedom of the rotational position of the movable element 13.

In the present embodiment, the controller 15 may rotate the movable element 13 around the rotation axis AX by the interaction between the magnetic field by the coil unit 22 of one stator 11 provided in front of the opening/closing door 17,18 and the magnetic field by the magnet unit 27 of the movable element 13. In this case, the movable element 13 can be rotated by controlling one stator 11, and therefore, the control is facilitated.

In the present embodiment, the controller 15 may rotate the movable element 13 around the rotation axis AX by the interaction between the magnetic field by the coil unit 22 of one stator 11 provided in front of the opening/closing door 17,18 and the coil unit 22 of the stator 11 adjacent to the one stator 11 and the magnetic field by the magnet unit 27 of the movable element 13. In this case, since the movable element 13 can be rotated at a position across the two stators 11, the degree of freedom of the rotational position of the movable element 13 can be improved. Further, since the movable element 13 can be rotated by the plurality of stators 11, the output of each stator 11 can be reduced, and the heat generation of the stator 11 can be reduced. Further, the size of each stator 11 can be reduced.

In the present embodiment, the transport path 19 may be formed in a ladder shape including a first transport path 19A and a second transport path 19B. In this case, the configuration and control can be simplified as compared with the case of the free track while allowing the planar movement of the movable element 13. In addition, in the case where a plurality of movable elements 13 are arranged, even when any one of the movable elements 13 is stopped due to a failure or the like, it is possible to perform passing, passing by, turning around, or the like by the other movable elements 13, and it is possible to continue the operation of the system. Therefore, the downtime of the system can be reduced.

In the present embodiment, the controller 15 may rotate the movable element 13 around the rotation axis AX at a position where at least a part of one of the stators 11 in the second transport path 19B and at least a part of the movable element 13 overlap each other when viewed from the Z-axis direction. In this case, even when the substrate support 13a of the movable element 13 is of a non-extensible type and is relatively long, the movable element 13 can be moved to the second transport path 19B so that the substrate support 13a is separated from the opening/closing door 17, and then the movable element 13 can be rotated to change the orientation of the substrate support 13a. Therefore, the transport system that can also cope with the non-extendable substrate support 13a can be constructed.

In the present embodiment, the controller 15 may rotate the movable element 13 around the rotation axis AX at a position where at least a part of one of the stators 11 in the connecting portion 19C and at least a part of the movable element 13 overlap each other when viewed from the Z-axis direction. When the second transport path 19B is positioned in front of the opening/closing door 17 of the processing chamber 9, the connecting portion 19C where the first transport path 19A and the second transport path 19B intersect is positioned immediately in front of the opening/closing door 17. As in the present embodiment, by rotating the movable element 13 at the connecting portion 19C, the orientation of the substrate support 13a can be changed immediately before the opening/closing door 17. This eliminates the need to retract the movable element 13 to the second transport path 19B for rotation, and the moving length of the movable element 13 can be minimized.

In the present embodiment, the controller 15 may move the movable element 13 so that the orientation of the substrate support 13a when moving on the first transport path 19A and the orientation of the substrate support 13a when moving on the second transport path 13a are the same. For example, when the movable element 13 does not carry the semiconductor substrate W into or out of the processing chamber 9 or the load lock chamber 5 but only moves on the transport path, it is not necessary to change the direction of the substrate support 13a. As in the present embodiment, the movable element 13 is moved with the substrate support 13a facing the same direction in the first transport path 19A and the second transport path 13a, and thus it is possible to suppress the rotation of the movable element 13 to the minimum necessary. This can shorten the tact time and improve the transfer efficiency of the semiconductor substrate W.

In the present embodiment, the controller 15 may adjust at least one of the position and the direction of the movable element 13 such that the position of the semiconductor substrate W is the position of the setting base Wp2 or Wp1 in the processing chamber 9 or the load lock chamber 5 at the position where at least a part of one of the stators 11 provided immediately before the opening/closing door 17, 18 and at least a part of the movable element 13 overlap each other. In this case, the position of the semiconductor substrate W can be finely adjusted, and therefore, the positional accuracy when the movable element 13 receives or delivers the semiconductor substrate W from or to the processing chamber 9 or the load lock chamber 5 can be improved.

### 6. Modified example

The disclosed embodiments are not limited to the above, and various modifications can be made without departing from the spirit and technical idea of the present disclosure. Such a modification will be described below.

### (6-1. Case where movable element is rotated in front of load lock chamber

In the above-described embodiment, when the semiconductor substrate W is carried into or carried out from the predetermined processing chamber 9, the movable element 13 is rotated on the stator 11 in front of the processing chamber 9, but the position where the direction of the movable element 13 is changed is not limited to the above. For example, the movable element 13 may be rotated in advance so that the substrate support 13a faces a predetermined direction on the stator 11 of the first transport path 19A connected to a predetermined load lock chamber 5 (the stator 11 in front of the load lock chamber 5), and the semiconductor substrate W may be carried into or carried out from the processing chamber 6 through the first transport path 19A or the second transport path 19B. Alternatively, the reverse operation may be performed.

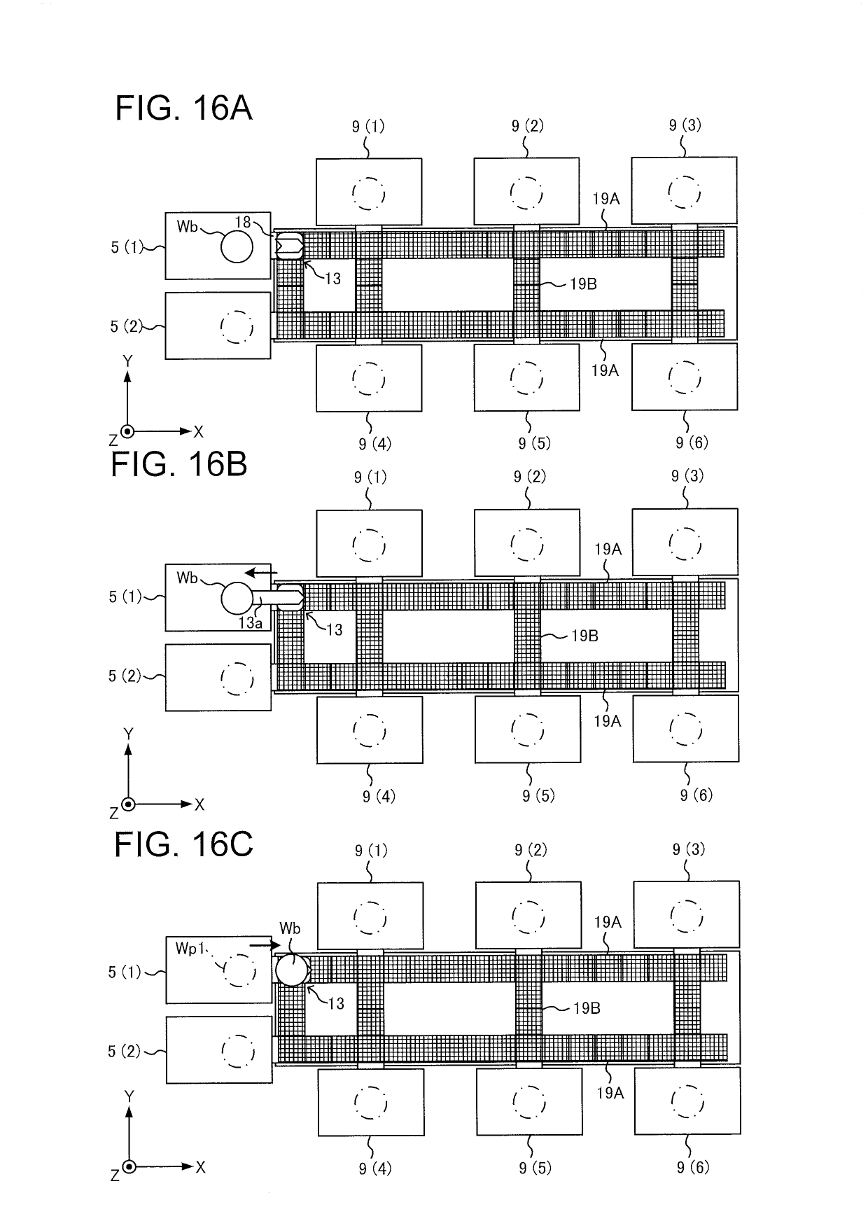

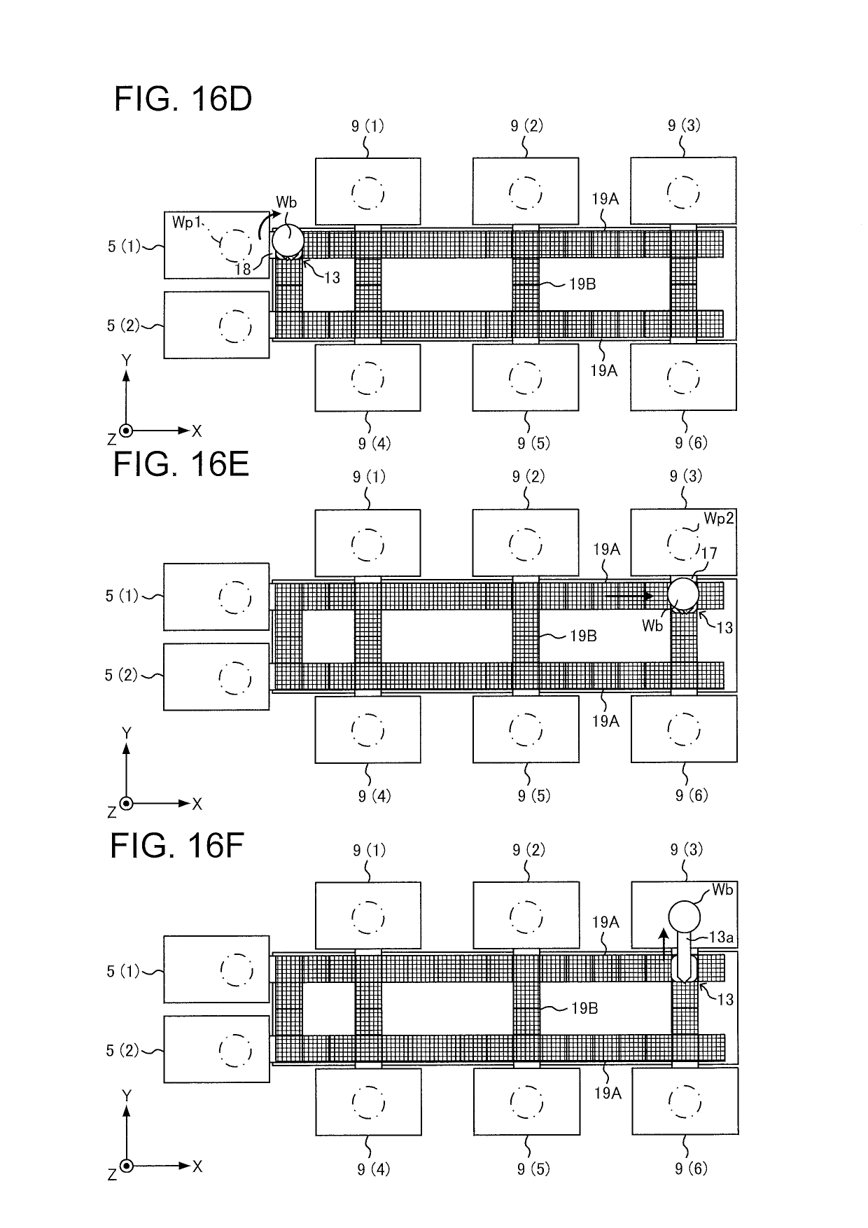

FIGS. 16A to 16F are diagrams illustrating, in a modified example in which the movable element 13 is rotated in front of the load lock chamber 5, an example of operation in which the movable element 13, provided with a single-arm extensible substrate support 13a, transfers an unprocessed semiconductor substrate Wb from the load lock chamber 5(1) to the processing chamber 9(3). First, as shown in FIG. 16A, the movable element 13 moves to a position above the stator 11 immediately before the opening/closing door 18 of the load lock chamber 5 (1), that is, a position facing the opening/closing door 18 of the load lock chamber 5 (1).

Next, as shown in FIG. 16B, the movable element 13 extends the substrate support 13a into the load lock chamber 5 (1) through the opened opening/closing door 18, and receives the unprocessed semiconductor substrate Wb placed on the setting base Wp1 of the load lock chamber 5 (1). The semiconductor substrate Wb is received by, for example, the lifting operation of the movable element 13 in the Z-axis direction, the rotating operation of the movable element 13 in the θy direction, or a lifter pin (not illustrated) provided in the load lock chamber 5 (1).

Next, as shown in FIG. 16C, the movable element 13 retracts the substrate support 13a, and carries the semiconductor substrate Wb out of the load lock chamber 5 (1).

Next, as shown in FIG. 16D, the movable element 13 rotates approximately 90° in the clockwise direction on the stator 11 immediately before the opening/closing door 18 of the load lock chamber 5 (1), and changes the direction of the substrate support 13a from the load lock chamber 5 (1) side to the positive side in the Y-axis direction.

Next, as shown in FIG. 16E, the movable element 13 moves on the first transport path 19A to a position above the stator 11 immediately before the opening/closing door 17 of the processing chamber 9 (3), that is, a position facing the opening/closing door 17 of the processing chamber 9 (3), in a state where the substrate support 13a faces the positive side in the Y-axis direction.

Next, as shown in FIG. 16F, the movable element 13 extends the substrate support 13a into the processing chamber 9 (3) through the opened opening/closing door 17, and transfers the semiconductor substrate Wb to the setting base Wp2 of the processing chamber 9 (3). The semiconductor substrate Wb is transferred by, for example, the lifting operation of the movable element 13 in the Z-axis direction, the rotating operation of the movable element 13 in the θx direction, or a lifter pin (not illustrated) provided in the processing chamber 9 (3).

Although the semiconductor substrate Wb is transferred from the load lock chamber 5 (1) to the processing chamber 9 (3) in the above description, the same operation as described above may be performed when the unprocessed semiconductor substrate Wb is transferred from the load lock chamber 5 (1) to the processing chamber 9 (1) or the processing chamber 9 (2). Further, when the unprocessed semiconductor substrate Wb is transferred from the load lock chamber 5 (2) to any one of the processing chambers 9 (4), 9 (5), and 9 (6), the same operation as described above may be performed. In addition, in contrast to the above, when the processed semiconductor substrate Wa is transferred from any one of the processing chambers 9 (1), 9 (2), and 9 (3) to the load lock chamber 5 (1), or when the processed semiconductor substrate Wa is transferred from any one of the processing chambers 9 (4), 9 (5), and 9 (6) to the load lock chamber 5 (2), the above operation may be performed in reverse.

When the unprocessed semiconductor substrate Wb is transferred from the load lock chamber 5 (1) to any of the processing chambers 9 (4), 9 (5), and 9 (6), the unprocessed semiconductor substrate Wb passes through any of the second transport paths 19B and moves onto the other first transport path 19A in the movement of the first transport path 19A shown in the above FIG. 16E, and the same operation may be performed. The same applies to the case where the unprocessed semiconductor substrate Wb is transferred from the load lock chamber 5 (2) to any of the processing chambers 9 (1), 9 (2), and 9 (3).

### 6-2. Case of Placing Temporary Storage

A temporary storage place where the semiconductor substrate W is temporarily placed may be provided in a space surrounded by the first transport path 19A and the second transport path 19B.

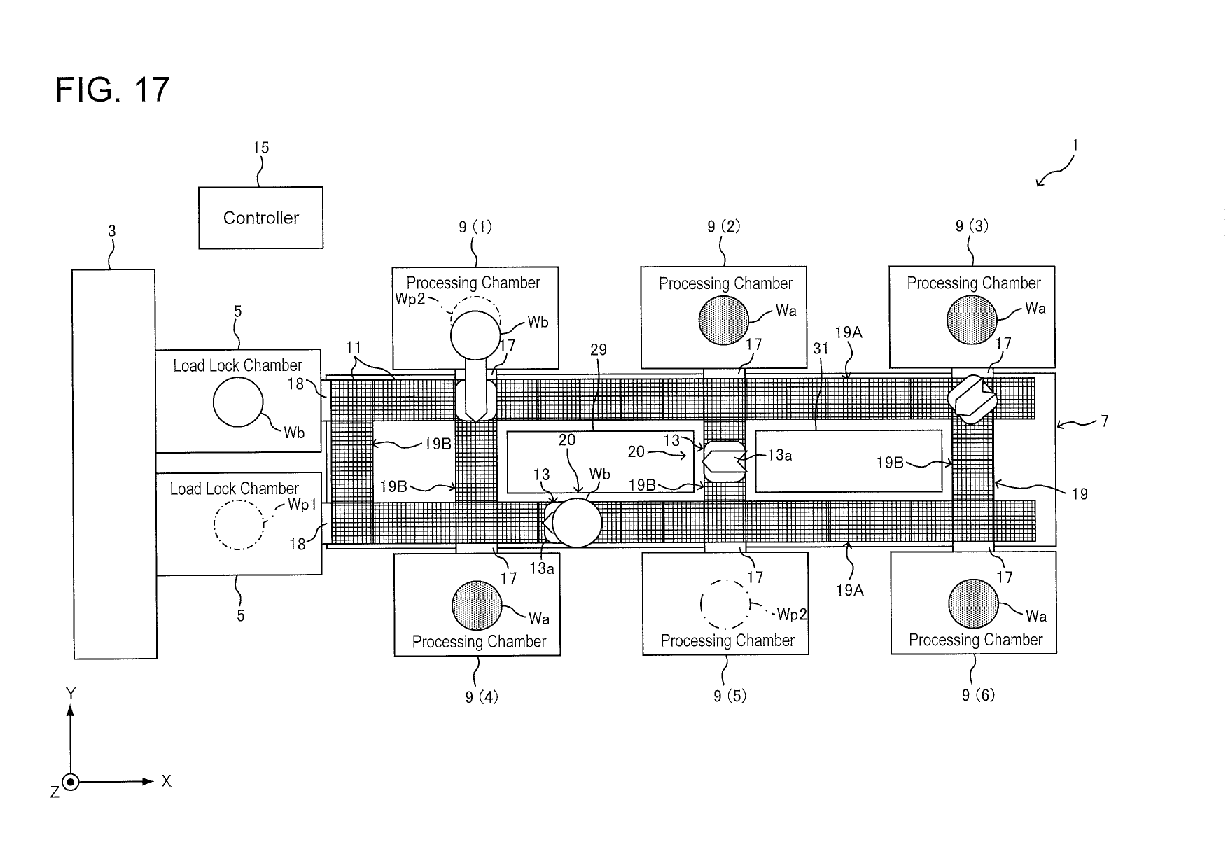

FIG. 17 is a diagram schematically illustrating an example of the overall configuration of the substrate transport system 1 in a modification in which a temporary storage place is arranged. In the example shown in FIG. 17, the temporary storage place 29 is provided in a space surrounded by two first transport paths 19A, a second transport path 19B provided in front of the processing chambers 9 (1) and 9 (4), and a second transport path 19B provided in front of the processing chambers 9 (2) and 9 (5). In addition, the temporary storage place 31 is provided in a space surrounded by the two first transport paths 19A, the second transport path 19B provided in front of the processing chambers 9 (2) and 9 (5), and the second transport path 19B provided in front of the processing chambers 9 (3) and 9 (6). In addition to the temporary storage place 29, 31, a temporary storage place may be provided in a space surrounded by the first transport path 19A and the second transport path 19B in the vicinity of the load lock chamber 5. The number of temporary storage places may be one.

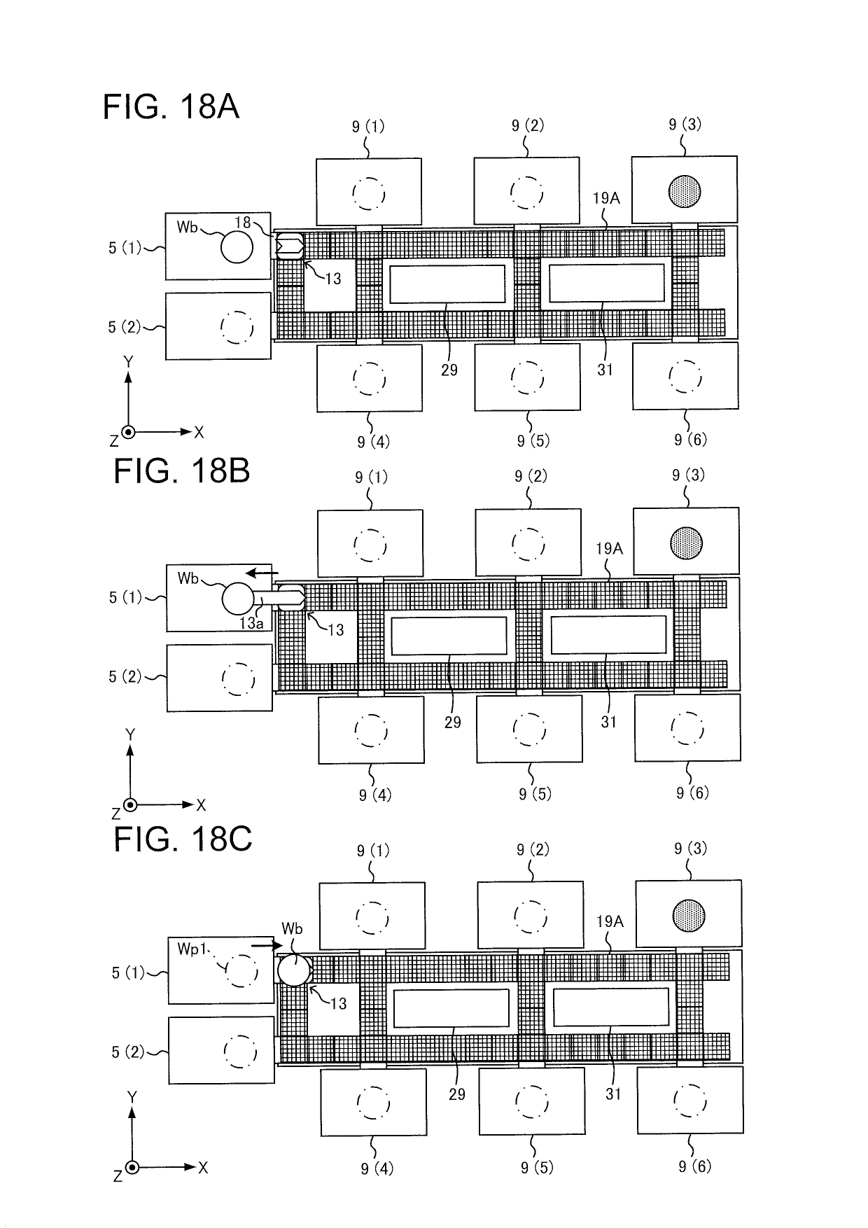

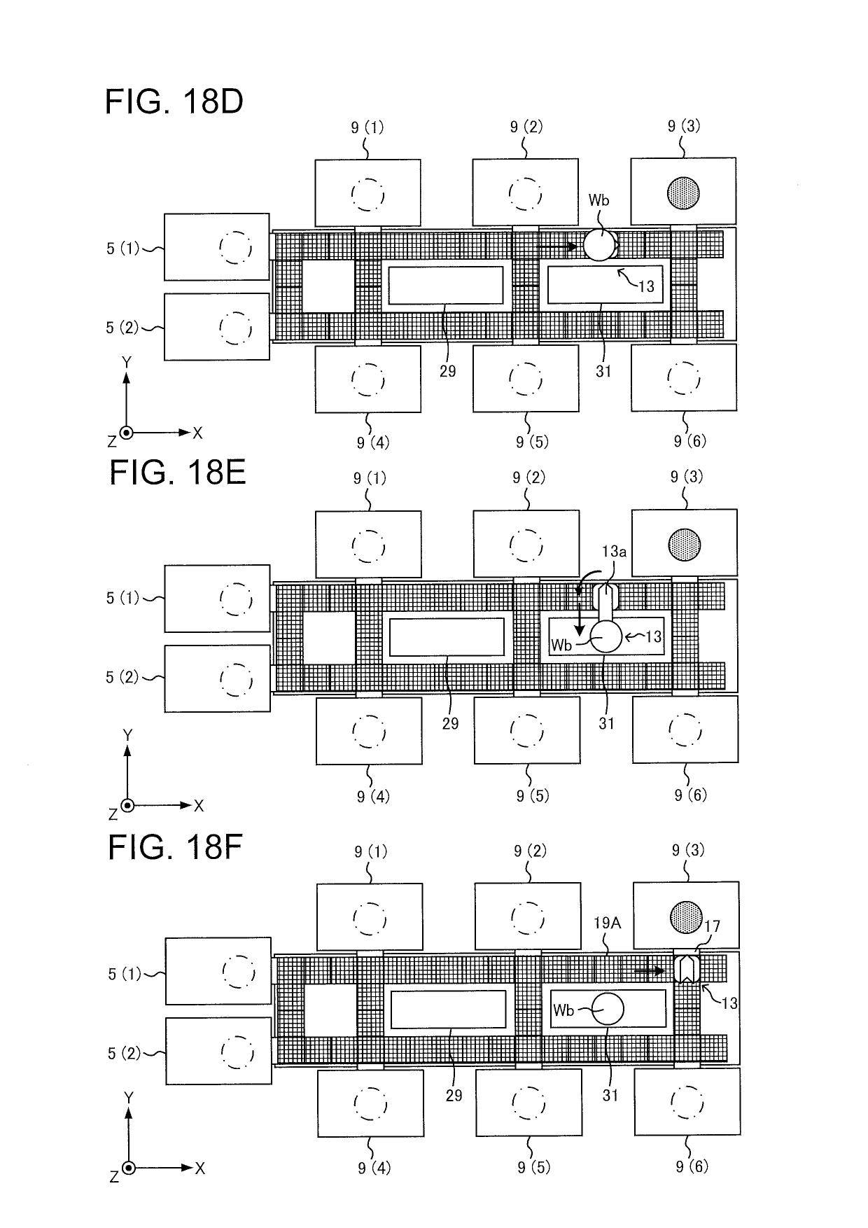

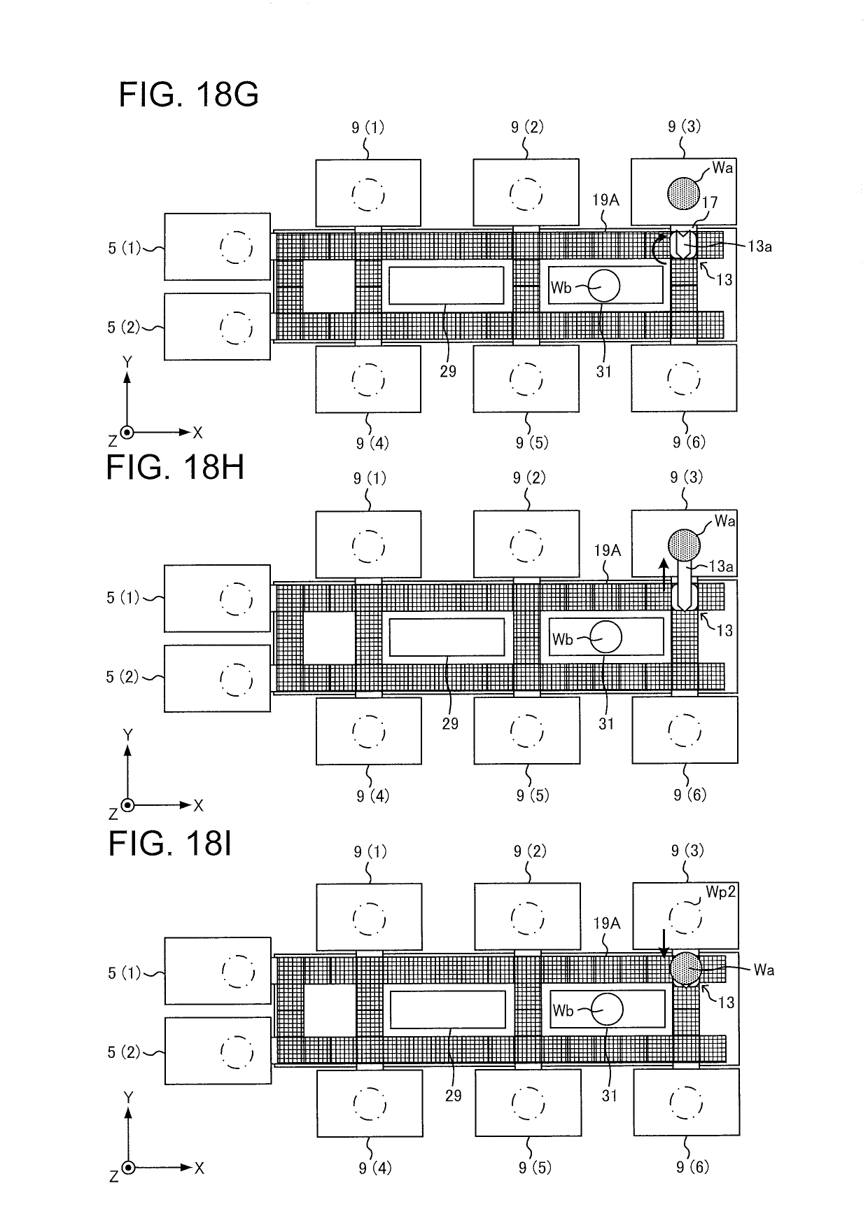

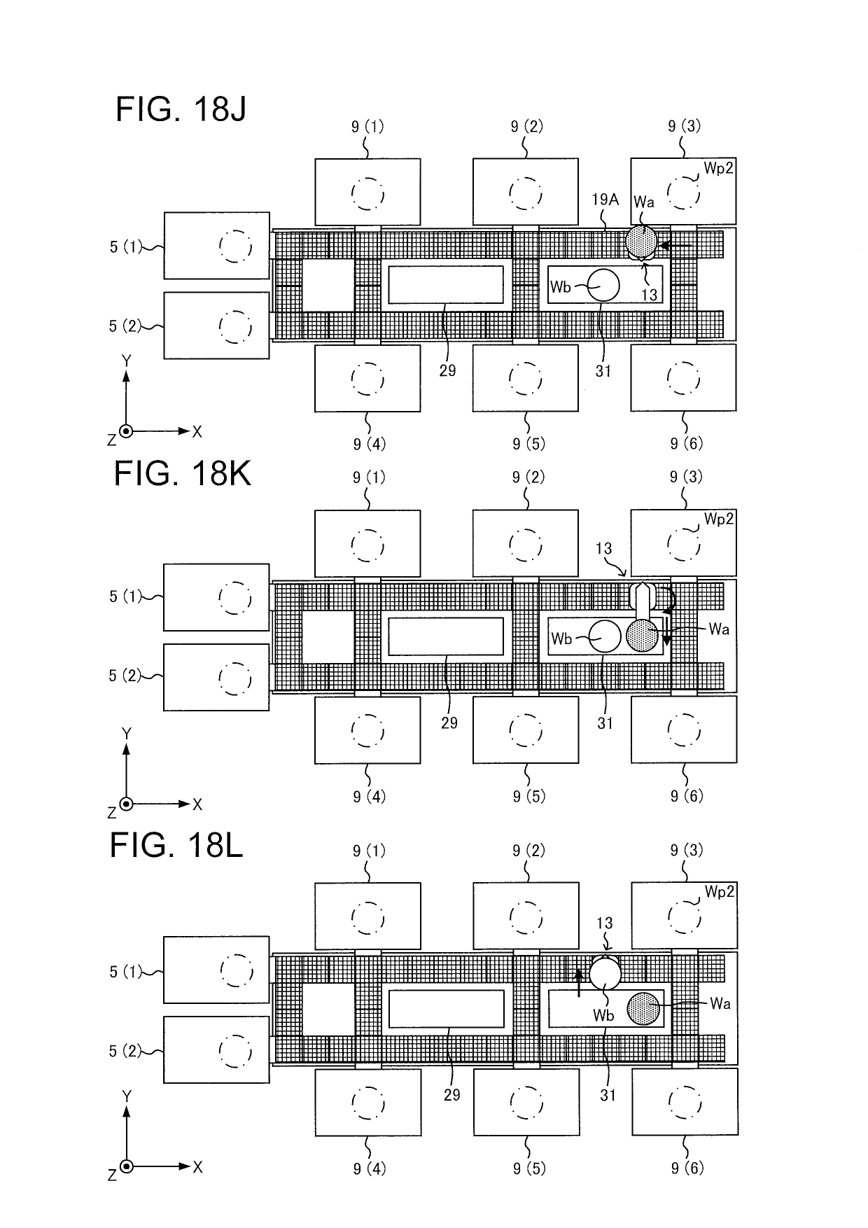

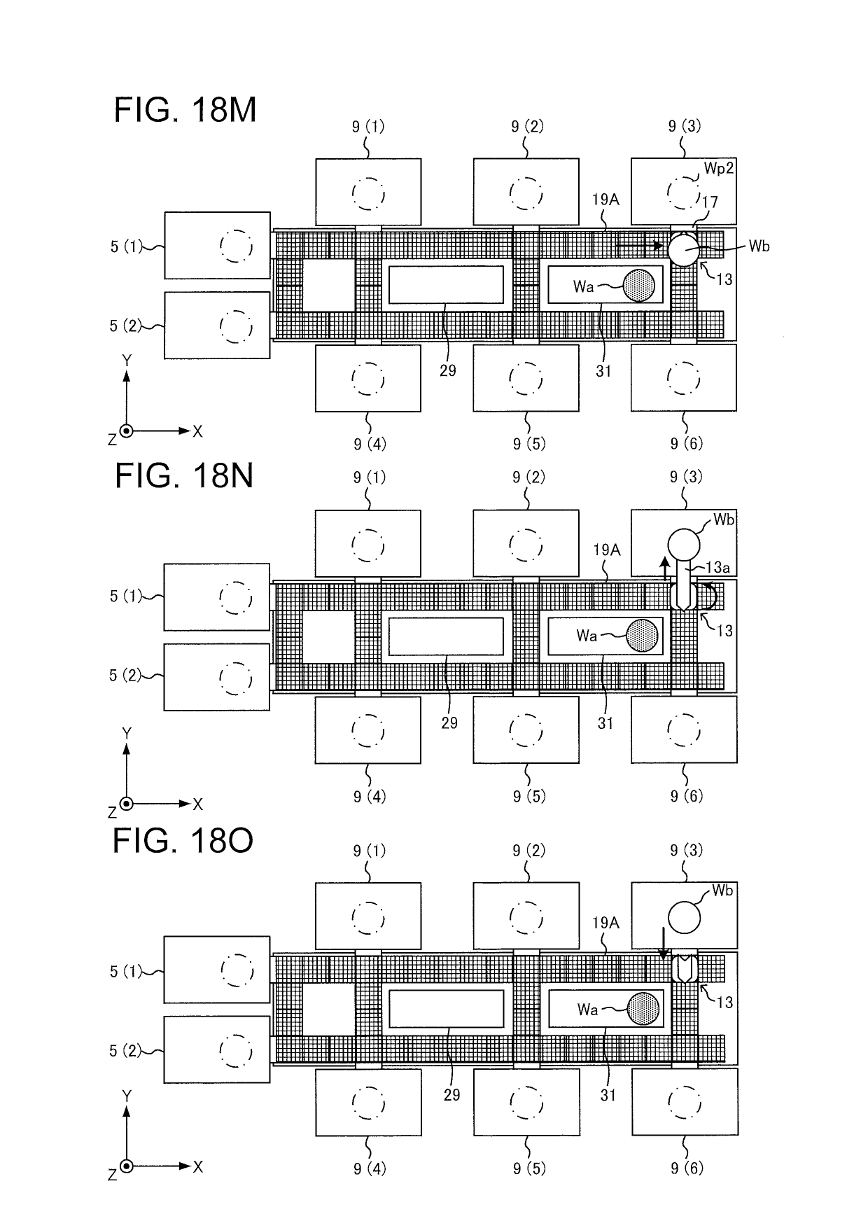

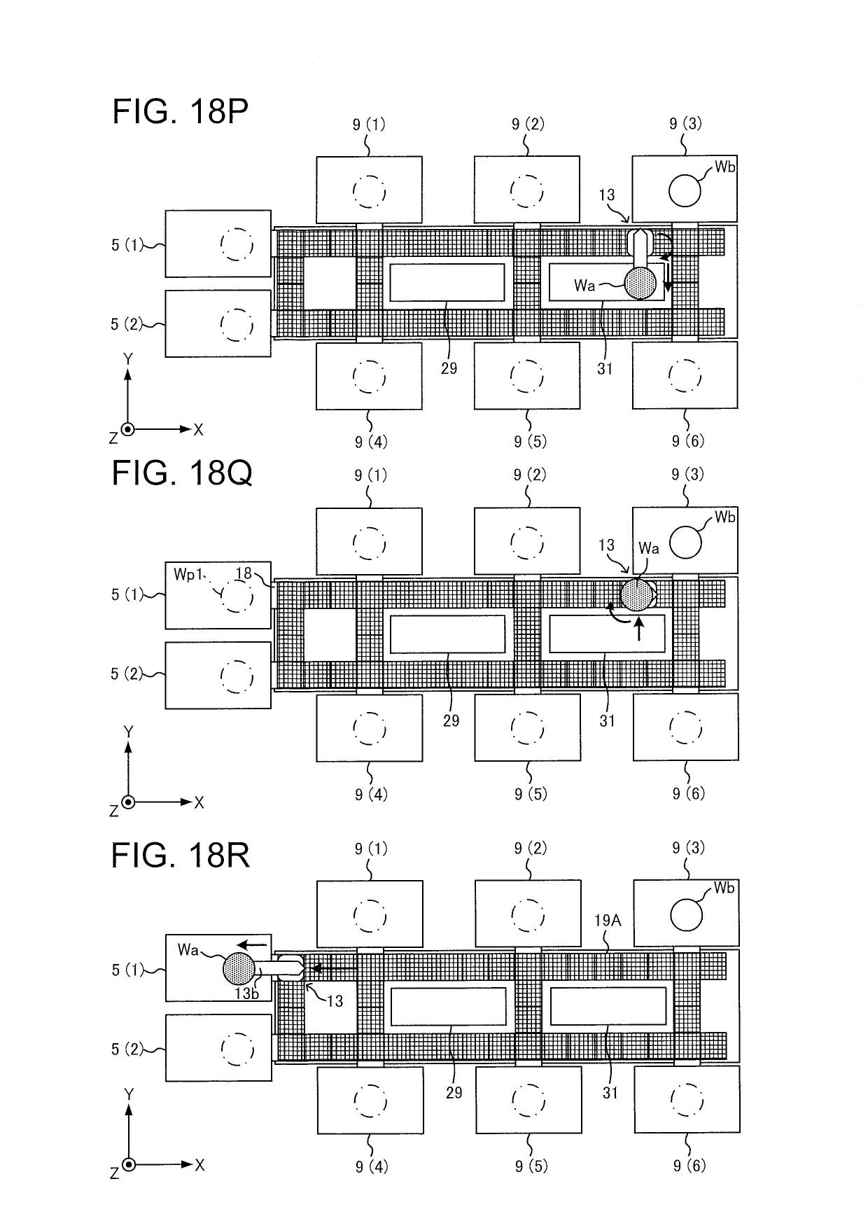

FIGS. 18A to 18R are diagrams illustrating an operation example in a case where the movable element 13 including, for example, the single-arm telescopic substrate support 13a transports the unprocessed semiconductor substrate Wb from the load lock chamber 5 (1) to the processing chamber 9 (3) and transports the processed semiconductor substrate Wa from the processing chamber 9 (3) to the load lock chamber 5 (1) in the modification example in which the temporary storage place is provided. First, as shown in FIG. 18A, the movable element 13 moves to a position above the stator 11 immediately before the opening/closing door 18 of the load lock chamber 5 (1), that is, a position facing the opening/closing door 18 of the load lock chamber 5 (1).

Next, as shown in FIG. 18B, the movable element 13 extends the substrate support 13a into the load lock chamber 5 (1) through the opened opening/closing door 18, and receives the unprocessed semiconductor substrate Wb placed on the setting base Wp1 of the load lock chamber 5 (1). The semiconductor substrate Wb is received by, for example, the lifting operation of the movable element 13 in the Z-axis direction, the rotating operation of the movable element 13 in the θy direction, or a lifter pin (not illustrated) provided in the load lock chamber 5 (1).

Next, as shown in FIG. 18C, the movable element 13 retracts the substrate support 13a, and carries the semiconductor substrate Wb out of the load lock chamber 5 (1).

Next, as shown in FIG. 18D, the movable element 13 moves on the first transport path 19A to a position above the stator 11 immediately before the temporary storage place 31 in the vicinity of the processing chamber 9 (3), that is, a position facing the temporary storage place 31, without changing the orientation of the substrate support 13a.

Next, as shown in FIG. 18E, the movable element 13 rotates approximately 90° in the counterclockwise direction on the stator 11 immediately before the temporary storage place 31, and changes the direction of the substrate support 13a from the load lock chamber 5 (1) side to the temporary storage place 31 side. The movable element 13 extends the substrate support 13a to the temporary storage place 31 and transfers the semiconductor substrate Wb to the temporary storage place 31. The semiconductor substrate Wb is transferred by, for example, the raising and lowering operation of the movable element 13 in the Z-axis direction, the rotating operation of the movable element 13 in the θx direction, or a lifter pin (not illustrated) provided in the temporary storage place 31.

Next, as shown in FIG. 18F, the movable element 13 moves on the first transport path 19A to a position above the stator 11 immediately before the opening/closing door 17 of the processing chamber 9 (3), that is, a position facing the opening/closing door 17 of the processing chamber 9 (3), in a state where the substrate support 13a is retracted and directed to the negative side in the Y-axis direction.

Next, as shown in FIG. 18G, the movable element 13 rotates approximately 180° in the clockwise direction or the counterclockwise direction on the stator 11 immediately before the opening/closing door 17 of the processing chamber 9 (3), and changes the direction of the substrate support 13a from the negative side in the Y-axis direction to the processing chamber 9 (3) side.

Next, as shown in FIG. 18H, the movable element 13 extends the substrate support 13a into the processing chamber 9 (3) through the opened opening/closing door 17, and receives the processed semiconductor substrate Wa placed on the setting base Wp2 of the processing chamber 9 (3). The semiconductor substrate Wa is received by, for example, the lifting operation of the movable element 13 in the Z-axis direction, the rotating operation of the movable element 13 in the θx direction, or a lifter pin (not illustrated) included in the processing chamber 9 (3).

Next, as shown in FIG. 18I, the movable element 13 retracts the substrate support 13a, and carries the semiconductor substrate Wa out of the processing chamber 9 (3).

Next, as shown in FIG. 18J, the movable element 13 moves on the first transport path 19A to a position above the stator 11 immediately before the temporary storage place 31 in the vicinity of the processing chamber 9 (3), that is, a position facing the temporary storage place 31, in a state where the substrate support 13a faces the positive side in the Y-axis direction.

Next, as shown in FIG. 18K, the movable element 13 rotates clockwise or counterclockwise by about 180° on the stator 11 immediately before the temporary storage place 31, and changes the direction of the substrate support 13a on which the semiconductor substrate Wa is mounted from the Y-axis positive side to the temporary storage place 31 side. The movable element 13 extends the substrate support 13a to the temporary storage place 31 and transfers the semiconductor substrate Wa to the temporary storage place 31. The semiconductor substrate Wa is transferred by, for example, the raising and lowering operation of the movable element 13 in the Z-axis direction, the rotating operation of the movable element 13 in the θx direction, or a lifter pin (not illustrated) provided in the temporary storage place 31.

Next, as shown in FIG. 18L, the movable element 13 retracts the substrate support 13a and moves on the first transport path 19A to a position above the stator 11 immediately before the semiconductor substrate Wb placed in the temporary storage place 31, that is, a position facing the semiconductor substrate Wb in the temporary storage place 31. The movable element 13 extends the substrate support 13a to the temporary storage place 31 and receives the semiconductor substrate Wb placed on the temporary storage place 31. The semiconductor substrate Wb is received by, for example, the raising and lowering operation of the movable element 13 in the Z-axis direction, the rotating operation of the movable element 13 in the θx direction, or a lifter pin (not illustrated) provided in the temporary storage place 31. Then, the movable element 13 contracts the substrate support 13a.

Next, as shown in FIG. 18M, the movable element 13 moves on the first transport path 19A to a position above the stator 11 immediately before the opening/closing door 17 of the processing chamber 9 (3), that is, a position facing the opening/closing door 17 of the processing chamber 9 (3), in a state where the substrate support 13a on which the semiconductor substrate Wb is mounted faces the negative side in the Y-axis direction.

Next, as shown in FIG. 18N, the movable element 13 rotates approximately 180° in the clockwise direction or the counterclockwise direction on the stator 11 immediately before the opening/closing door 17 of the processing chamber 9 (3), and changes the direction of the substrate support 13a on which the semiconductor substrate Wb is mounted from the negative side in the Y-axis direction to the processing chamber 9 (3) side. The movable element 13 extends the substrate support 13a into the processing chamber 9 (3) through the opened door 17, and transfers the substrate Wb to the setting base Wp2 of the processing chamber 9 (3). The semiconductor substrate Wa is transferred by, for example, the lifting operation of the movable element 13 in the Z-axis direction, the rotating operation of the movable element 13 in the θx direction, or a lifter pin (not illustrated) provided in the processing chamber 9 (3).

Next, as shown in FIG. 18O, the movable element 13 contracts the substrate support 13a.

Next, as shown in FIG. 18P, the movable element 13 moves on the first transport path 19A to a position above the stator 11 immediately before the semiconductor substrate Wa placed in the temporary storage place 31, that is, a position facing the semiconductor substrate Wa in the temporary storage place 31, with the substrate support 13a facing the positive side in the Y-axis direction. The movable element 13 rotates substantially 180° in the clockwise direction or the counterclockwise direction to change the direction of the substrate support 13a from the positive side in the Y-axis direction to the temporary storage place 31 side. The movable element 13 extends the substrate support 13a to the temporary storage place 31 and receives the semiconductor substrate Wa placed on the temporary storage place 31. The semiconductor substrate Wa is received by, for example, the raising and lowering operation of the movable element 13 in the Z-axis direction, the rotating operation of the movable element 13 in the θx direction, or a lifter pin (not illustrated) provided in the temporary storage place 31.

Next, as shown in FIG. 18Q, the movable element 13 contracts the substrate support 13a. The movable element 13 is rotated clockwise by about 90° to change the direction of the substrate support 13a on which the semiconductor substrate Wa is mounted from the temporary storage place 31 side to the load lock chamber 5 (1) side.

Next, as shown in FIG. 18R, the movable element 13 moves on the first transport path 19A to a position above the stator 11 immediately before the opening/closing door 18 of the load lock chamber 5 (1), that is, a position facing the opening/closing door 18 of the load lock chamber 5 (1). The movable element 13 extends the substrate support 13a into the load lock chamber 5 (1) through the opened door 18, and transfers the processed semiconductor substrate Wa to the setting base Wp1 of the load lock chamber 5 (1). The semiconductor substrate Wa is transferred by, for example, the lifting operation of the movable element 13 in the Z-axis direction, the rotation operation of the movable element 13 in the θy direction, or a lifter pin (not illustrated) provided in the load lock chamber 5 (1).

Although the semiconductor substrate W is carried in and out between the load lock chamber 5 (1) and the processing chamber 9 (3) in the above description, the same operation as described above may be performed when the semiconductor substrate W is carried in and out between the load lock chamber 5 (1) and the processing chamber 9 (1) or the processing chamber 9 (2). In this case, the temporary storage place 29 may be used. Further, when the semiconductor substrate W is carried in and out between the load lock chamber 5 (2) and any one of the processing chambers 9 (4), 9 (5), and 9 (6), the same operation as described above may be performed. When the substrate W is transferred between the load lock chamber 5 (1) and any one of the processing chambers 9 (4), 9 (5), and 9 (6), the substrate W may pass through any one of the second transport paths 19B and move onto the other first transport path 19A in the movement of the first transport path 19A shown in FIG. 18D, FIG. 18F, and FIG. 18F, and the same operation may be performed. The same applies to the case where the semiconductor substrate W is carried in and out between the load lock chamber 5 (2) and any one of the processing chambers 9 (1), 9 (2), and 9 (3).

### 6-3. Others

Although the case where the coil unit 22 included in the stator 11 is configured by a concentrated winding coil has been described above, the coil unit 22 may be configured by a distributed winding coil.

In the above description, the case where the transport path 19 is formed in a substantially ladder shape (ladder shape) has been described, but the transport path 19 may have a form other than the above. For example, the stators 11 may be laid on the entire floor of the vacuum transfer chamber 7. The stator 11 may not have substantially the same dimensions as the movable element 13. For example, the dimensions of the stator 11 may be made larger than those of the movable element 13 so that a plurality of movable elements 13 can pass by one stator 11.

In addition, although the case of transporting the semiconductor substrate W as an example of the workpiece has been described above, the transport system may be configured to transport the workpiece other than the semiconductor substrate W and execute a predetermined process.

In the above description, when there is a description such as "vertical", "parallel", or "plane", the description is not in a strict sense. The terms "perpendicular", "parallel", and "plane" mean "substantially perpendicular", "substantially parallel", and "substantially plane", respectively, with design and manufacturing tolerances and errors allowed.

In the above description, when there is a description such as "same", “similar", "equal", or "different" in terms of dimension, size, shape, position, or the like in appearance, the description does not have a strict meaning. The terms “same", “similar", "equal", and "different" allow tolerances and errors in design and manufacturing, and mean "substantially same", "substantially similar", "substantially equal", and "substantially different".

In addition to the above description, the methods according to the above embodiment and the respective modifications may be appropriately combined and used. In addition, although not illustrated one by one, the above-described embodiment and each modification example are implemented with various modifications added thereto within a range not departing from the gist thereof.

The problems to be solved by the embodiments and the modifications described above and the effects of the embodiments and the modifications are not limited to the above description. Depending on the embodiment, the modification, and the like, a problem not described above can be solved, an effect not described above can be achieved, only a part of the described problems can be solved, and only a part of the described effects can be achieved.

What is claimed is:

1. A transport system comprising:
a first chamber including a transport path along which a workpiece is configured to be transported;
a second chamber arranged around the first chamber and including an opening/closing door;
a plurality of stators arranged along the transport path in the first chamber, each of the plurality of stators including a coil;
a movable element including a magnet and a support configured to support the workpiece, the moving element being configured to float on and move along the transport path to carry the workpiece supported on the support into and out of the second chamber; and
a controller configured to control the movable element to change an orientation of the movable element so as to change an orientation of the support at a position where at least a part of one of the plurality of stators provided in front of the opening/closing door and at least a part of the movable element overlap with each other when viewed in a vertical direction.

2. The transport system according to claim 1,
wherein the controller is configured to rotate the movable element to rotate around a rotation axis along the vertical direction at a position where the one of the plurality of stators provided in front of the opening/closing door and the rotation axis overlap when viewed from the vertical direction.

3. The transport system according to claim 2,
wherein the controller is configured to rotate the movable element around the rotation axis by an interaction between a magnetic field generated by the coil of the one of the plurality of stators provided in front of the opening/closing door and a magnetic field generated by the magnet of the movable element.

4. The transport system according to claim 2,
wherein the controller is configured to rotate the movable element around the rotation axis by an interaction between a magnetic field generated by the magnet of the movable element and magnetic fields generated by the coil of the one of the plurality of stators provided in front of the opening/closing door and generated by the coil of a stator adjacent to the one of the plurality of stators provided in front of the opening/closing door.

5. The transport system according to claim 1,
wherein the transport path comprises
two first transport paths in which the plurality of the stators are arranged in a line along a first direction of the first chamber, and
at least one second transport path in which at least one of the plurality of stators is arranged in a line along a second direction intersecting the first direction, the second transport path connecting the two first transport paths in the second direction, and
wherein the controller is configured to rotate the movable element around a rotation axis at a position where at least a part of the movable element and at least a part of the one of the plurality of stators in the first transport path or the second transport path overlap when viewed from the vertical direction.

6. The transport system according to claim 5,
wherein the second transport path extends along the second direction in front of the opening/closing door and connects the two first transport paths, and
wherein the controller is configured to rotate the movable element around the rotation axis at a position where at least a part of the one of the plurality of stators in the second transport path and at least a part of the movable element overlap when viewed from the vertical direction.

7. The transport system according to claim 6,
wherein the transport path has a connecting portion where the first transport path and the second transport path intersect, and
wherein the controller is configured to rotate the movable element around the rotation axis at a position where the at least the part of the one of the plurality of stators in the connecting portion and the at least the part of the movable element overlap when viewed in the vertical direction.

8. The transport system according to claim 5, wherein the controller is configured to move the movable element such that an orientation of the support when moving on the first transport path is the same as an orientation of the support when moving on the second transport path.

9. The transport system according to claim 1, wherein the controller is configured to adjust at least one of a position and an orientation of the movable element such that a position of the workpiece becomes a predetermined position in the second chamber at a position where the at least a part of one stator arranged immediately before the opening/closing door among the plurality of stators and the at least the part of the movable element overlap.

10. The transport system according to claim 5, further comprising:
a temporary storage place where the workpiece is temporarily placed and that is arranged in a space surrounded by the first transport path and the second transport path.

11. A transport system comprising:
a first chamber including a transport path along which a workpiece is configured to be transported;
a second chamber arranged around the first chamber and including an opening/closing door;
a plurality of stators arranged along the transport path in the first chamber, each of the plurality of stators including a coil;
a movable element including a magnet and a support configured to support the workpiece, the moving element being configured to float on and move along the transport path to carry the workpiece supported on the support into and out of the second chamber; and
a controller configured to control the movable element to
change an orientation of the movable element so as to change an orientation of the support at a position where at least a part of one of the plurality of stators provided in front of the opening/closing door and at least a part of the movable element overlap with each other when viewed in a vertical direction, and adjust at least one of a position and an orientation of the movable element at a position where at least a part of one stator arranged immediately before the opening/closing door among the plurality of stators and at least a part of the movable element overlap when viewed in the vertical direction such that the workpiece is positioned at a predetermined position in the second chamber.

12. A method for transporting a workpiece, comprising:
providing a first chamber including a transport path along which a workpiece is configured to be transported;
providing a second chamber arranged around the first chamber and including an opening/closing door;
providing a plurality of stators arranged along the transport path in the first chamber, each of the plurality of stators including a coil;
providing a movable element including a magnet and a support configured to support the workpiece, the moving element being configured to float on and move along the transport path to carry the workpiece supported on the support into and out of the second chamber; and
changing an orientation of the movable element so as to change an orientation of the support at a position where at least a part of one of the plurality of stators provided in front of the opening/closing door and at least a part of the movable element overlap with each other when viewed in a vertical direction.
